(19) United States
(12) Patent Application Publication
(10) Pub. No.: US 2019/0101672 A1
(43) Pub. Date: Apr. 4, 2019

(54) OPTICAL FILTER AND APPARATUS USING OPTICAL FILTER

(71) Applicant: JSR CORPORATION, Minato-ku (JP)

(72) Inventors: Tatsuya KASAI, Minato-ku (JP); Katsuya NAGAYA, Minato-ku (JP); Toshihiro OTSUKI, Minato-ku (JP)

(73) Assignee: JSR CORPORATION, Minato-ku (JP)

(21) Appl. No.: 16/078,238

(22) PCT Filed: Mar. 15, 2017
(86) PCT No.: PCT/JP2017/010319

§ 371 Date: Dec. 13, 2018

(30) Foreign Application Priority Data
Mar. 22, 2016 (JP) 2016-057119

(51) Int. Cl. G02B 5/20; H01L 27/146; G02B 5/00

(52) U.S. Cl. CPC G02B 5/20; G02B 5/003; H01L 27/1462

(57) ABSTRACT

The object of the present invention is to provide an optical filter which has not only a high visible light transmittance, but also high light cut characteristics in the near-infrared wavelength region, and which is excellent in heat resistance. The optical filter of the present invention comprises a base material comprising a compound (S) having an absorption maximum in the region of 600 to 1150 nm and an antioxidant (P) having at least one phosphorus atom in a molecule, and a dielectric multilayer film formed on at least one surface of the base material.

### TECHNICAL FIELD

The present invention relates to an optical filter and a device using an optical filter. More particularly, the present invention relates to an optical filter which comprises a base material comprising a compound having absorption in a specific wavelength region and an antioxidant having a specific structure, and a solid-state image pickup device and a camera module each of which uses the optical filter.

### BACKGROUND ART

In solid-state image pickup devices, such as video cameras, digital still cameras and cellular phones having camera function, a CCD or CMOS image sensor that is a solid-state imaging element of color image is used. In such a solid-state imaging element, silicon photo diode having sensitivity to near-infrared rays that cannot be perceived by human eye is used in its light-receiving section. For such a solid-state imaging element, it is necessary to make correction of visibility so that a natural color might be obtained when an image is seen with human eye, and an optical filter (e.g., near-infrared cut filter) to selectively transmit or cut rays of specific wavelength region is frequently used.

As such optical filters, those manufactured by various methods have been used in the past. For example, a near-infrared cut filter in which a transparent resin is used as a base material and a near-infrared absorbing dye is incorporated into the transparent resin is known (see, for example, Patent literature 1).

As a result of earnest studies, the present applicant has found that a transparent resin substrate containing a near-infrared absorbing dye having an absorption maximum in a specific wavelength region can be used to provide a near-infrared cut filter less changed in optical properties even by the change in the incident angle, and has proposed a near-infrared cut filter having both of a wide viewing angle and a high visible light transmittance (see Patent literature 2).

### CITATION LIST

### Patent Literature

Patent literature 1: Japanese Patent Laid-Open Publication No. 1994-200113

Patent literature 2: Japanese Patent Laid-Open Publication No. 2011-100084

### SUMMARY OF INVENTION

### Technical Problem

In recent years, image quality levels required for camera images have also been increasingly enhanced considerably with respect to mobile devices and the like, and optical filters have also been required to have a high visible light transmittance and high light cut characteristics in the near-infrared wavelength region. Conventional optical filters, however, have not been sufficient in heat resistance performance of near-infrared absorbing dyes adopted, and such optical filters have been problematic in terms of dye decomposition during a heating process in production and also long-term reliability in some cases. In particular, such problems tend to be remarkably caused in a dye where the absorption wavelength is more than 800 nm, because the HOMO energy of the molecule of such a dye is higher (the molecule is instabilized).

The object of the present invention is to provide an optical filter which has not only a high visible light transmittance, but also high light cut characteristics in the near-infrared wavelength region, and which is excellent in heat resistance.

### Solution to Problem

The present inventors have earnestly studied in order to solve the above problem. As a result, the present inventors have found that an optical filter which has not only a high visible light transmittance, but also high light cut characteristics in the near-infrared wavelength region, and which is excellent in heat resistance performance is obtained by combining a compound having an absorption maximum in a specific wavelength region with an antioxidant having at least one phosphorus atom in a molecule, and they have accomplished the present invention. Embodiments of the present invention are shown below.

[1] An optical filter comprising:

a base material comprising a compound (S) having an absorption maximum in the region of 600 to 1150 nm and an antioxidant (P) having at least one phosphorus atom in a molecule; and

a dielectric multilayer film formed on at least one surface of the base material.

[2] The optical filter according to [1], wherein the base material comprises a resin.

[3] The optical filter according to [2], wherein the resin is a transparent resin.

[4] The optical filter according to [3], wherein the content of the antioxidant (P) is in the range of 0.1 to 3.0 parts by weight based on 100 parts by weight of the transparent resin.

[5] The optical filter according to any one of [1] to [4], wherein the melting point of the antioxidant (P) is 100 to 250° C.

[6] The optical filter according to any one of [1] to [5], wherein the antioxidant (P) is a compound having a structure represented by the following formula (p).

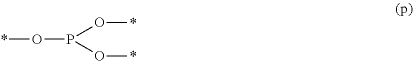 [SMILES: *OP(O*)O*]

In the formula (p), * represents a bond.

[7] The optical filter according to any one of [1] to [6], wherein the antioxidant (P) is at least one selected from compounds represented by the following formulae (I) to (III).

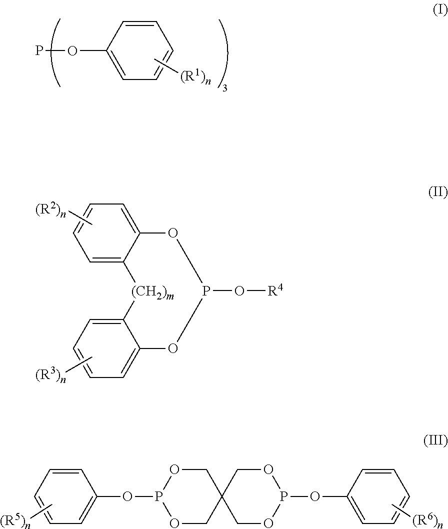

In the formulae (I) to (III), R¹ to R⁵ are each independently a hydrogen atom; a halogen atom; a substituted or unsubstituted hydrocarbon group of 1 to 30 carbon atoms, which may have a linking group containing an oxygen atom, a sulfur atom, a nitrogen atom or a silicon atom; or a polar group, n is an integer of 0 to 5, and m is 0 or 1.

[8] The optical filter according to [3] or [4], wherein the transparent resin is at least one selected from the group consisting of a cyclic (poly)olefin-based resin, an aromatic polyether-based resin, a polyimide-based resin, a fluorene polycarbonate-based resin, a fluorene polyester-based resin, a polycarbonate-based resin, a polyamide-based resin, a polyarylate-based resin, a polysulfone-based resin, a polyether sulfone-based resin, a polyparaphenylene-based resin, a polyamideimide-based resin, a polyethylene naphthalate-based resin, a fluorinated aromatic polymer-based resin, a (modified) acrylic-based resin, an epoxy-based resin, an allyl ester-based curing type resin, a silsesquioxane-based ultraviolet curing resin, an acrylic-based ultraviolet curing resin and a vinyl-based ultraviolet curing resin.

[9] The optical filter according to any one of [1] to [8], which selectively transmits visible rays and a part of near-infrared rays.

[10] A solid-state image pickup device equipped with the optical filter according to any one of [1] to [9].

[11] A camera module equipped with the optical filter according to any one of [1] to [9].

### Advantageous Effects of Invention

According to the present invention, an optical filter which has not only a high visible light transmittance, but also high light cut characteristics in the near-infrared wavelength region, and which is excellent in heat resistance performance can be provided by combining a compound having an absorption maximum in a specific wavelength region with an antioxidant having at least one phosphorus atom in a molecule.

### BRIEF DESCRIPTION OF DRAWINGS

FIG. 1 is a schematic view showing a method for measuring a transmittance in the case where the transmittance is measured in the perpendicular direction to an optical filter.

FIG. 2 is a spectral transmission spectrum of a base material obtained in Example 2.

FIG. 3 is a schematic view showing a preferable configuration example of the optical filter of the present invention.

FIG. 4 is a spectral transmission spectrum of an optical filter obtained in Example 2.

FIG. 5 is a spectral transmission spectrum of an optical filter obtained in Example 20.

FIG. 6 is a spectral transmission spectrum of a base material obtained in Comparative Example 1.

### DESCRIPTION OF EMBODIMENTS

The present invention is specifically described hereinafter.

[Optical Filter]

The optical filter of the present invention comprises a base material (i) comprising a compound (S) having an absorption maximum in the wavelength region of 600 nm to 1150 nm and an antioxidant (P) having at least one phosphorus atom in a molecule, and a dielectric multilayer film formed on at least one surface of the base material (i). The optical filter of the present invention, thus constituted, has not only a high visible light transmittance, but also high light cut characteristics in the near-infrared wavelength region, and is excellent in heat resistance.

When the optical filter of the present invention is used for a solid-state imaging element or the like, the visible light transmittance is preferably higher and the transmittance in the near-infrared wavelength region is preferably lower. Specifically, in the wavelength region of 430 to 580 nm, the average transmittance measured in the perpendicular direction to the optical filter is preferably not less than 75%, more preferably not less than 80%, still more preferably not less than 83%, particularly preferably not less than 85%. In the wavelength region of 800 to 1150 nm, the average transmittance measured in the perpendicular direction to the optical filter is preferably not more than 5%, more preferably not more than 4%, still more preferably not more than 3%, particularly preferably not more than 2%. When the average transmittance in this wavelength region is in the above range and when the optical filter of the present invention is used for a solid-state imaging element, such use is preferable because near-infrared rays can be sufficiently cut and excellent color reproducibility can be attained.

When the optical filter of the present invention is used for, for example, a solid-state imaging element also having a near-infrared sensing function, the optical filter has a light stopband Za, a light passband Zb and a light stopband Zc in the wavelength region of 700 to 1100 nm. The relationship of the wavelengths of these bands is Za<Zb<Zc. The center wavelengths of these bands may herein satisfy the “Za<Zb<Zc”, and these bands may be each partially overlapped with other hands on the longer wavelength side or on the shorter wavelength side. For example, Za on the longer wavelength side and Zb on the shorter wavelength side may be partially overlapped with each other. The maximum transmittance of the light (near-infrared rays) passband Zb is preferably higher, and the minimum transmittance of each of the light stopbands Za and Zc is desirably lower.

The dielectric multilayer film in the present invention is a film having an ability to reflect near-infrared rays. In the present invention, such a near-infrared reflecting film may be provided on one surface of the base material (i), or may be provided on both surfaces thereof. When the near-infrared reflecting film is provided on one surface, production cost and ease of production are excellent, and when the near-infrared reflecting film is provided on both surfaces, an optical filter having high strength and rarely suffering warpage and distortion can be obtained. When the optical filter is applied to uses such as a solid-state imaging element, warpage and distortion of the optical filter are preferably smaller, and therefore, it is preferable to provide the dielectric multilayer film on both surfaces of the base material (i).

The thickness of the optical filter of the present invention has only to be properly selected according to the desired use, but according to the recent trend toward reduction in thickness and weight and so on of a solid-state image pickup device, also the thickness of the optical filter of the present invention is preferably smaller. Since the optical filter of the present invention includes the base material (i), reduction in thickness is feasible.

The thickness of the optical filter of the present invention is, for example, preferably not more than 200 μm, more preferably not more than 180 μm, still more preferably not more than 150 μm, particularly preferably not more than 120 μm, and the lower limit is desirably, for example, 20 μm though it is not specifically restricted.

[Base Material (i)]

The base material (i) comprises the compound (S) and the antioxidant (P), and preferably further comprises a resin, more preferably a transparent resin. Hereinafter, a layer containing at least one selected from the compound (S) and the antioxidant (P), and a transparent resin is also referred to as a “transparent resin layer”, and a resin layer other than that is also referred to as a “resin layer” simply.

The base material (i) may be a single-layer base material or a multilayer base material. When the base material (i) is a single-layer base material, there can be mentioned, for example, a base material formed of a transparent resin substrate (ii) containing the compound (s) and the antioxidant (P), and the transparent resin substrate (ii) serves as the transparent resin layer. In the case of a multilayer base material, there can be mentioned, for example, a base material in which a transparent resin layer such as an overcoat layer formed from a curable resin containing the compound (S) and the antioxidant (P) is laminated on a support such as a glass support or a resin support that becomes a base, a base material in which a resin layer such as an overcoat layer formed from a curable resin containing the antioxidant (P) is laminated on a transparent resin substrate (iii) containing compound (S), a base material in which a resin layer such as an overcoat layer formed from a curable resin containing the compound (S) is laminated on a transparent resin substrate (iv) containing the antioxidant (P), and a base material in which a resin layer such as an overcoat layer formed from a curable resin is laminated on a transparent resin substrate (ii) containing the compound (S) and the antioxidant (P). From the viewpoints of not only production cost and ease of optical property control, but also attainment of flaw erasing effect for a resin support or a transparent resin substrate (ii) and enhancement in flaw resistance of the base material (i), a base material in which a resin layer such as an overcoat layer formed from a curable resin is laminated on a transparent resin substrate (ii) containing the compound (S) and the antioxidant (P) is particularly preferable.

The average transmittance of the base material (i) in the wavelength region of 430 to 580 nm is preferably not less than 75%, still more preferably not less than 78%, particularly preferably not less than 80%. When the base material having such transmission properties is used, high light transmission properties can be attained in the visible region, and a highly sensitive camera function can be attained.

The thickness of the base material (i) can be properly selected according to the desired use and is not specifically restricted. However, the thickness is preferably 10 to 200 μm, still more preferably 15 to 180 μm, particularly preferably 20 to 150 μm.

When the thickness of the base material (i) is in the above range, the optical filter using the base material (i) can be reduced in thickness and weight, and can be preferably applied to various uses such as a solid-state image pickup device. Especially when the base material (i) formed of the transparent resin substrate (ii) is used for a lens unit of a camera module or the like, reduction in height and weight of the lens unit can be realized, so that such use is preferable.

<Compound (S)>

The compound (S) is not specifically restricted provided that it is a compound having an absorption maximum in the wavelength region of 600 nm to 1150 nm. This compound is preferably a solvent-soluble type dye compound, and is more preferably at least one kind selected from the group consisting of a squarylium-based compound, a phthalocyanine-based compound, a cyanine-based compound, a naphthalocyanine-based compound, a pyrrolopyrrole-based compound, a croconium-based compound, a hexaphyrin-based compound, a metal dithiolate-based compound, a diimonium-based compound and a ring-expanded BODIPY (borondipyromethene)-based compound, further preferably a squarylium-based compound, a phthalocyanine-based compound, a metal dithiolate-based compound or a diimonium-based compound. Specific examples of the compound (S) include compounds represented by the following formulae (A) to (E). By the use of such a compound (S), high near-infrared cutting properties and favorable visible light transmittance near the absorption maximum can be attained at the same time.

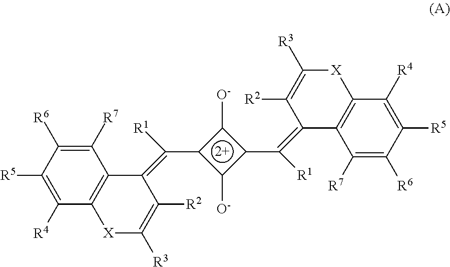

In the formula (A), each X is independently an oxygen atom, a sulfur atom, a selenium atom, a tellurium atom or —NR⁸—, R¹ to R⁸ are each independently a hydrogen atom, a halogen atom, a sulfo group, a hydroxyl group, a cyano group, a nitro group, a carboxyl group, a phosphoric acid group, a —NR^{g}R^{h} group, a —SRⁱ group, a —SO₂Rⁱ group, a —OSO₂Rⁱ group or any one of the following L^{a} to L^{h}, R^{g} and R^{h} are each independently a hydrogen atom, a —C(O)Rⁱ group or any one of the following L^{a} to L^{e}, and Rⁱ is any one of the following L^{a} to L^{e},

(L^{a}) an aliphatic hydrocarbon group of 1 to 12 carbon atoms
(L^{b}) a halogen-substituted alkyl group of 1 to 12 carbon atoms
(L^{c}) an alicyclic hydrocarbon group of 3 to 14 carbon atoms
(L^{d}) an aromatic hydrocarbon group of 6 to 14 carbon atoms
(L^{e}) a heterocyclic group of 3 to 14 carbon atoms
(L^{f}) an alkoxy group of 1 to 12 carbon atoms
(L^{g}) an acyl group of 1 to 12 carbon atoms, which may have a substituent L, or
(L^{h}) an alkoxycarbonyl group of 1 to 12 carbon atoms, which may have a substituent L, and

the substituent L is at least one kind selected from the group consisting of an aliphatic hydrocarbon group of 1 to 12 carbon atoms, a halogen-substituted alkyl group of 1 to 12 carbon atoms, an alicyclic hydrocarbon group of 3 to 14 carbon atoms, an aromatic hydrocarbon group of 6 to 14 carbon atoms and a heterocyclic group of 3 to 14 carbon atoms.

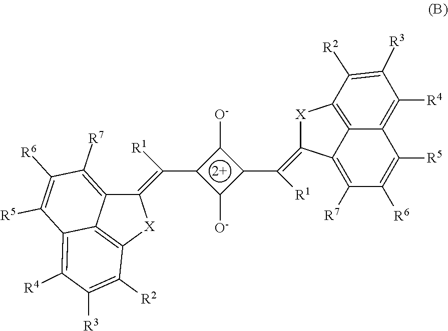

In the formula (B), each X is independently an oxygen atom, a sulfur atom, a selenium atom, a tellurium atom or —NR⁸—, R¹ to R⁸ are each independently a hydrogen atom, a halogen atom, a sulfo group, a hydroxyl group, a cyano group, a nitro group, a carboxyl group, a phosphoric acid group, a —NR^{g}R^{h} group, a —SRⁱ group, a —SO₂Rⁱ group, a —OSO₂Rⁱ group or any one of the following L^{a} to L^{h}, R^{g} and R^{h} are each independently a hydrogen atom, a —C(O)Rⁱ group or any one of the following L^{a} to L^{e}, and Rⁱ is any one of the following L^{a} to L^{e},

(L^{a}) an aliphatic hydrocarbon group of 1 to 12 carbon atoms
(L^{b}) a halogen-substituted alkyl group of 1 to 12 carbon atoms
(L^{c}) an alicyclic hydrocarbon group of 3 to 14 carbon atoms
(L^{d}) an aromatic hydrocarbon group of 6 to 14 carbon atoms
(L^{e}) a heterocyclic group of 3 to 14 carbon atoms
(L^{f}) an alkoxy group of 1 to 12 carbon atoms
(L^{g}) an acyl group of 1 to 12 carbon atoms, which may have a substituent L, or
(L^{h}) an alkoxycarbonyl group of 1 to 12 carbon atoms, which may have a substituent L, and

the substituent L is at least one kind selected from the group consisting of an aliphatic hydrocarbon group of 1 to 12 carbon atoms, a halogen-substituted alkyl group of 1 to 12 carbon atoms, an alicyclic hydrocarbon group of 3 to 14 carbon atoms, an aromatic hydrocarbon group of 6 to 14 carbon atoms and a heterocyclic group of 3 to 14 carbon atoms.

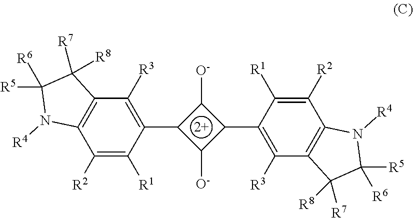

In the formula (C), R¹ to R³ are each independently a hydrogen atom, a halogen atom, a sulfo group, a hydroxyl group, a cyano group, a nitro group, a carboxyl group, a phosphoric acid group, a —NR^{g}R^{h} group, a —SRⁱ group, a —SO₂Rⁱ group, a —OSO₂Rⁱ group or any one of the following L^{a} to L^{h}, R^{g} and R^{h} are each independently a hydrogen atom, a —C(O)Rⁱ group or any one of the following L^{a} to L^{e}, and Rⁱ is any one of the following L^{a} to L^{e},

(L^{a}) an aliphatic hydrocarbon group of 1 to 12 carbon atoms
(L^{b}) a halogen-substituted alkyl group of 1 to 12 carbon atoms
(L^{c}) an alicyclic hydrocarbon group of 3 to 14 carbon atoms
(L^{d}) an aromatic hydrocarbon group of 6 to 14 carbon atoms
(L^{e}) a heterocyclic group of 3 to 14 carbon atoms
(L^{f}) an alkoxy group of 1 to 12 carbon atoms
(L^{g}) an acyl group of 1 to 12 carbon atoms, which may have a substituent L, or
(L^{h}) an alkoxycarbonyl group of 1 to 12 carbon atoms, which may have a substituent L, and

the substituent L is at least one kind selected from the group consisting of an aliphatic hydrocarbon group of 1 to 12 carbon atoms, a halogen-substituted alkyl group of 1 to 12 carbon atoms, an alicyclic hydrocarbon group of 3 to 14 carbon atoms, an aromatic hydrocarbon group of 6 to 14 carbon atoms and a heterocyclic group of 3 to 14 carbon atoms.

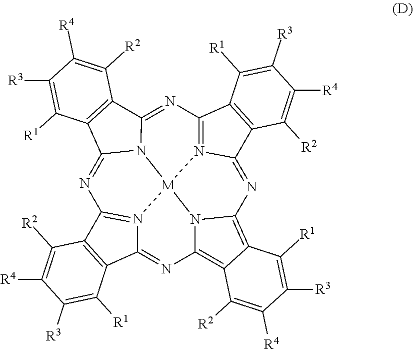

In the formula (D), M represents two hydrogen atoms, two monovalent metal atoms, a divalent metal atom, or substituted metal atoms containing a trivalent or tetravalent metal atom, R¹ to R² are each independently L¹, R¹ to R⁴ are each independently a hydrogen atom, a halogen atom, L¹ or —SO₂-L²,

L¹ is the following L^{a}, L^{b} or L^{c}, and L² is the following L^{a}, L^{b}, L^{c}, L^{d} or L^{e},

(L^{a}) an aliphatic hydrocarbon group of 1 to 12 carbon atoms
(L^{b}) a halogen-substituted alkyl group of 1 to 12 carbon atoms
(L^{c}) an alicyclic hydrocarbon group of 3 to 14 carbon atoms
(L^{d}) an aromatic hydrocarbon group of 6 to 14 carbon atoms, or
(L^{e}) a heterocyclic group of 3 to 14 carbon atoms, and

the above L^{a} to L^{e} may further have at least one substituent L selected from the group consisting of an aliphatic hydrocarbon group of 1 to 12 carbon atoms, a halogen-substituted alkyl group of 1 to 12 carbon atoms, an alicyclic hydrocarbon group of 3 to 14 carbon atoms, an aromatic hydrocarbon group of 6 to 14 carbon atoms, a heterocyclic group of 3 to 14 carbon atoms and an alkoxy group of 1 to 12 carbon atoms.

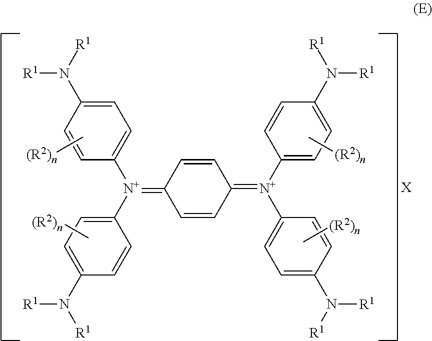

In the formula (E), R¹ to R² are each independently a hydrogen atom, a halogen atom, a sulfo group, a hydroxyl group, a cyano group, a nitro group, a carboxy group, a phosphoric acid group, a —NR^{g}R^{h} group, a —SRⁱ group, a —SO₂Rⁱ group, a —OSO₂Rⁱ group or any one of the following L^{a} to L^{h}, R^{g} and R^{h} are each independently a hydrogen atom, a —C(O)Rⁱ group or any one of the following L^{a} to L^{e}, and Rⁱ is any one of the following L^{a} to L^{e},

(L^{a}) an aliphatic hydrocarbon group of 1 to 12 carbon atoms
(L^{b}) a halogen-substituted alkyl group of 1 to 12 carbon atoms
(L^{c}) an alicyclic hydrocarbon group of 3 to 14 carbon atoms
(L^{d}) an aromatic hydrocarbon group of 6 to 14 carbon atoms
(L^{e}) a heterocyclic group of 3 to 14 carbon atoms
(L^{f}) an alkoxy group of 1 to 12 carbon atoms
(L^{g}) an acyl group of 1 to 12 carbon atoms, which may have a substituent L, or
(L^{h}) an alkoxycarbonyl group of 1 to 12 carbon atoms, which may have a substituent L,

the substituent L is at least one kind selected from the group consisting of an aliphatic hydrocarbon group of 1 to 12 carbon atoms, a halogen-substituted alkyl group of 1 to 12 carbon atoms, an alicyclic hydrocarbon group of 3 to 14 carbon atoms, an aromatic hydrocarbon group of 6 to 14 carbon atoms and a heterocyclic group of 3 to 14 carbon atoms,

n is an integer of 0 to 4, and

X is an anion required for neutralizing electric charge.

Specific examples of the compound represented by the formula (A) include compounds (s-1) to (s-40) described in the following Table 1.

TABLE 1

| | | | Substituent | | | | | | | |
|---|---|---|---|---|---|---|---|---|---|---|
| Compound | Structure | X | R¹ | R² | R³ | R⁴ | R⁵ | R⁶ | R⁷ | R⁸ |
| (s-1) | Formula | O | H | H | H | H | H | H | H | — |
| (s-2) | (A) | S | H | H | Me | H | H | H | H | — |
| (s-3) | | Se | H | H | Me | H | H | H | H | — |
| (s-4) | | —NR⁸— | Me | H | H | H | H | H | H | H |
| (s-5) | | O | H | H | t-Bu | H | H | H | H | — |
| (s-6) | | O | Me | H | Et | H | H | H | H | — |
| (s-7) | | S | H | H | t-Bu | H | Me | H | H | — |
| (s-8) | | O | H | H | i-Bu | H | H | Me | H | — |
| (s-9) | | Se | H | Me | i-Pr | H | H | 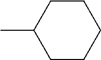 | H | — |
| (s-10) | | S | Me | Me | Me | H | H | H | Me | — |
| (s-11) | | O | H | H | t-Bu | H | H | i-Pr | H | — |
| (s-12) | | O | H | H | 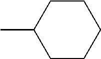 | H | Me | H | Me | — |
| (s-13) | | —NR⁸— | H | H | t-Bu | H | 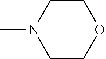 | H | H | Me |
| (s-14) | | O | H | H | t-Bu | H | 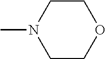 | H | H | — |
| (s-15) | | S | H | H | t-Bu | H | 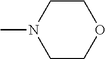 | H | H | — |
| (s-16) | | O | H | H | t-Bu | H | Me | Me | H | — |
| (s-17) | | S | Et | H | Et | Me | —N(CH₂CH₃) | H | H | — |
| (s-18) | | O | H | H | i-Pr | H | H | 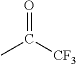 | H | — |
| (s-19) | | O | H | H | t-Bu | Me | H | Me | H | — |
| (s-20) | | O | Me | H | Me | H | 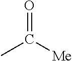 | H | H | — |
| (s-21) | | S | H | H | t-Bu | 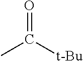 | H | H | H | — |
| (s-22) | | O | H | H | t-Bu | H | H | Cl | H | — |
| (s-23) | | O | H | H | t-Bu | H | Me | Cl | H | — |
| (s-24) | | O | H | H | t-Bu | Cl | H | t-Bu | H | — |
| (s-25) | | O | H | H | t-Bu | Cl | H | i-Pr | H | — |
| (s-26) | | Te | Me | H | F | H | H | t-Bu | H | — |
| (s-27) | | S | H | H | t-Bu | H | H | i-Pr | H | — |
| (s-28) | | S | H | H | t-Bu | Cl | H | t-Bu | H | — |
| (s-29) | | S | H | Cl | t-Bu | H | H | t-Bu | H | — |
| (s-30) | | O | H | H | t-Bu | H | 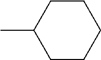 | F | H | — |
| (s-31) | | O | H | H | t-Bu | H | H | 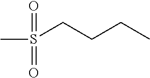 | H | — |
| (s-32) | | —NR⁸— | H | H | t-Bu | H | Et | 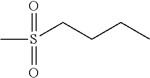 | t-Bu | n-Bu |
| (s-33) | | O | H | H | i-Pr | H | Me | 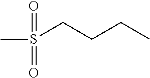 | H | — |
| (s-34) | | S | H | Et | t-Bu | H | H | 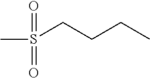 | H | — |
| (s-35) | | S | H | H | t-Bu | H | H | —OMe | H | — |
| (s-36) | | S | H | H | t-Bu | Me | H | —OEt | H | — |
| (s-37) | | —NR⁸— | H | H | t-Bu | H | H | t-Bu | H | n-Bu |
| (s-38) | | S | H | H | i-Pr | H | H | Cl | Me | — |
| (s-39) | | S | H | H | t-Bu | H | H | —SMe | H | — |
| (s-40) | | S | H | H | 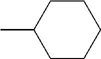 | H | H | —SEt | H | — |

Specific examples of the compound represented by the formula (B) include compounds (s-41) to (s-58) described in the following Table 2.

TABLE 2

| | | | Substituent | | | | | | | |
|---|---|---|---|---|---|---|---|---|---|---|
| Compound | Structure | X | R¹ | R² | R³ | R⁴ | R⁵ | R⁶ | R⁷ | R⁸ |
| (s-41) | Formula | O | H | H | H | H | H | H | H | — |
| (s-42) | (B) | —NR⁸— | H | H | Me | Me | H | H | H | H |
| (s-43) | | S | H | H | t-Bu | H | Me | H | H | — |
| (s-44) | | —NR⁸— | H | H | H | H | H | H | H | n-Bu |
| (s-45) | | —NR⁸— | H | H | H | H | H | H | H | —C₉H₁₈CH₃ |
| (s-46) | | O | Me | H | H | H | H | Cl | H | — |
| (s-47) | | —NR⁸— | H | H | i-Pr | H | H | H | H | n-Pr |
| (s-48) | | O | H | Et | H | H | H | Me | Cl | — |
| (s-49) | | S | H | H | t-Bu | H | H | 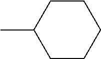 | H | — |
| (s-50) | | —NR⁸— | H | H | t-Bu | H | H | 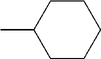 | H | —C₉H₁₈CH₃ |
| (s-51) | | O | Et | H | H | F | H | i-Pr | H | — |
| (s-52) | | —NR⁸— | H | H | 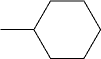 | H | Me | H | Me | t-Bu |
| (s-53) | | —NR⁸— | H | H | t-Bu | H | 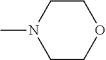 | H | H | n-Bu |
| (s-54) | | —NR⁸— | H | H | i-Pr | H | H | 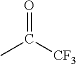 | H | —C₉H₁₈CH₃ |
| (s-55) | | O | H | H | t-Bu | 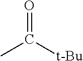 | H | Me | H | — |
| (s-56) | | —NR⁸— | Me | H | Me | H | 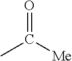 | H | H | Et |
| (s-57) | | —NR⁸— | H | H | H | H | H | —OMe | H | —C₉H₁₈CH₃ |
| (s-58) | | —NR⁸— | H | H | H | H | H | —SMe | H | —C₉H₁₈CH₃ |

Specific examples of the compound represented by the formula (C) include compounds (s-59) to (s-64) described in the following Table 3.

TABLE 3

| Com- | Struc- | Substituent | | | | | | | |
|---|---|---|---|---|---|---|---|---|---|
| pound | ture | R¹ | R² | R³ | R⁴ | R⁵ | R⁶ | R⁷ | R⁸ |
| (5-59) | For- mula (C) | 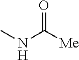 | H | H | Me | Me | H | Me | Me |
| (s-60) | | 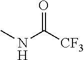 | H | H | Me | Me | H | Me | Me |
| (s-61) | | 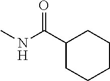 | H | H | Me | Me | H | Me | Me |
| (s-62) | | 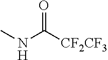 | H | H | Et | Me | H | Me | Me |
| (s-63) | | 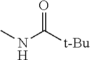 | H | H | Me | Me | H | Me | Me |
| (5-64) | | 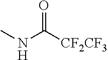 | H | H | iPr | Me | H | Me | Me |

Specific examples of the compound represented by the formula (D) include compounds (s-65) to (s-99) described in the following Table 4.

TABLE 4

| | | | Substituent | | | |
|---|---|---|---|---|---|---|
| Compound | Structure | M | R¹ | R² | R³ | R⁴ |
| (s-65) | Formula | Ni | Me | Me | H | H |
| (s-66) | (D) | Cu | Me | Me | H | H |
| (s-67) | | VO | Et | Et | H | H |
| (s-68) | | VO | Me | Me | Me | Me |
| (s-69) | | Cu | Et | Et | Me | Me |
| (s-70) | | Cu | n-Pr | n-Pr | H | H |
| (s-71) | | Cu | n-Bu | n-Bu | H | H |
| (s-72) | | VO | n-Bu | n-Bu | H | H |
| (s-73) | | Ni | n-Bu | n-Bu | Et | Et |
| (s-74) | | Co | —(CH₂)₅CH₃ | —(CH₂)₅CH₃ | H | H |
| (s-75) | | Cu | —(CH₂)₅CH₃ | —(CH₂)₅CH₃ | H | H |
| (s-76) | | VO | —(CH₂)₅CH₃ | —(CH₂)₅CH₃ | H | H |
| (s-77) | | Cu | —(CH₂)₈CH₃ | —(CH₂)₈CH₃ | H | H |
| (s-78) | | VO | —(CH₂)₈CH₃ | —(CH₂)₈CH₃ | H | H |
| (s-79) | | Zn | i-Pr | i-Pr | H | H |
| (s-80) | | TiO | t-Bu | t-Bu | Me | Me |
| (s-81) | | Cu | t-Bu | t-Bu | H | H |
| (s-82) | | VO | Me | Me | t-Bu | H |
| (s-83) | | VO | Me | Me | t-Bu | t-Bu |
| (s-84) | | Cu | 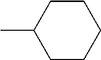 | 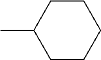 | H | H |
| (s-85) | | Ni | 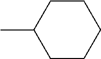 | 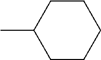 | F | F |
| (s-86) | | Cu | —(CH₂)₅CH₃ | —(CH₂)₅CH₃ | 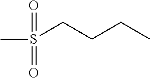 | H |
| (s-87) | | VO | —(CH₂)₅CH₃ | —(CH₂)₅CH₃ | 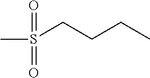 | H |
| (s-88) | | VO | Et | Et | 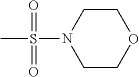 | H |
| (s-89) | | VO | Et | Et | 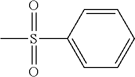 | H |
| (s-90) | | Cu | —(CF₂)₃CF₃ | —(CF₂)₃CF₃ | H | H |
| (s-91) | | VO | —(CF₂)₃CF₃ | —(CF₂)₃CF₃ | H | H |
| (s-92) | | Zn | —(CF₂)₃CF₃ | —(CF₂)₃CF₃ | H | H |
| (s-93) | | Co | —(CF₂)₅CF₃ | —(CF₂)₅CF₃ | t-Bu | H |
| (s-94) | | VO | —CF₃ | —CF₃ | 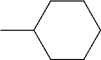 | H |
| (s-95) | | Cu | Et | n-Bu | H | H |
| (s-96) | | VO | Et | n-Bu | H | H |
| (s-97) | | Ni | Me | n-Pr | H | H |
| (s-98) | | VO | —CF₃ | n-Bu | H | H |
| (s-99) | | Cu | —CF₃ | n-Bu | t-Bu | H |

Specific examples of the compound represented by the formula (E) include compounds (s-100) to (s-113) described in the following Table 5. In the formula (E), X is an anion required for neutralizing electric charge, and one molecule is required when the anion is divalent and two molecules are required when the anion is monovalent. X is not specifically restricted provided that X is any of such anions. One example thereof includes anions (X-1) to (X-28) described in the following Table 6.

TABLE 5

| | | Anion | |
|---|---|---|---|
| Compound | Structure of dication moiety | Structure | Number |
| (s-100) | 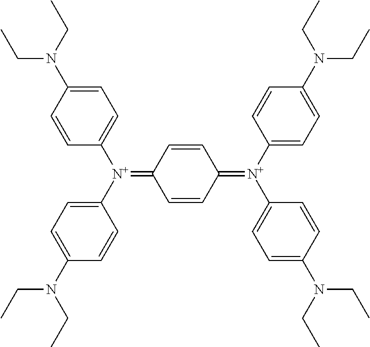 [SMILES: CCN(CC)c1ccc([N+](=C2C=CC(=[N+](c3ccc(N(CC)CC)cc3)c3ccc(N(CC)CC)cc3)C=C2)c2ccc(N(CC)CC)cc2)cc1] | (X-4) | 2 |
| (s-101) | 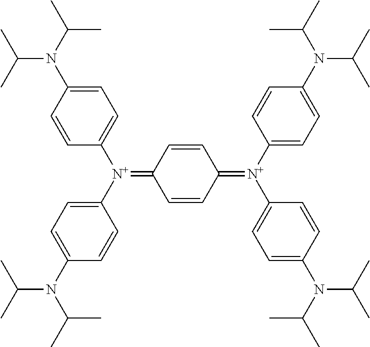 [SMILES: CC(C)N(c1ccc([N+](=C2C=CC(=[N+](c3ccc(N(C(C)C)C(C)C)cc3)c3ccc(N(C(C)C)C(C)C)cc3)C=C2)c2ccc(N(C(C)C)C(C)C)cc2)cc1)C(C)C] | (X-7) | 2 |
| (s-102) | 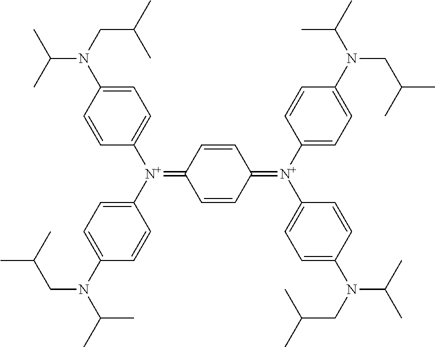 [SMILES: CC(C)CN(c1ccc([N+](=C2C=CC(=[N+](c3ccc(N(CC(C)C)C(C)C)cc3)c3ccc(N(CC(C)C)C(C)C)cc3)C=C2)c2ccc(N(CC(C)C)C(C)C)cc2)cc1)C(C)C] | (X-11) | 2 |
| (s-103) | 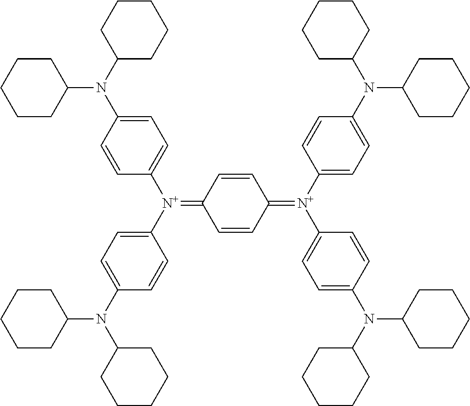 [SMILES: C1=CC(=[N+](c2ccc(N(C3CCCCC3)C3CCCCC3)cc2)c2ccc(N(C3CCCCC3)C3CCCCC3)cc2)C=CC1=[N+](c1ccc(N(C2CCCCC2)C2CCCCC2)cc1)c1ccc(N(C2CCCCC2)C2CCCCC2)cc1] | (X-14) | 1 |
| (s-104) | 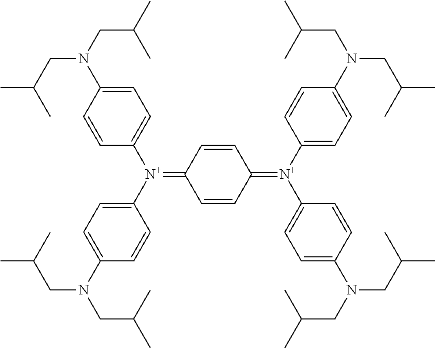 [SMILES: CC(C)CN(CC(C)C)c1ccc([N+](=C2C=CC(=[N+](c3ccc(N(CC(C)C)CC(C)C)cc3)c3ccc(N(CC(C)C)CC(C)C)cc3)C=C2)c2ccc(N(CC(C)C)CC(C)C)cc2)cc1] | (X-16) | 2 |
| (s-105) | 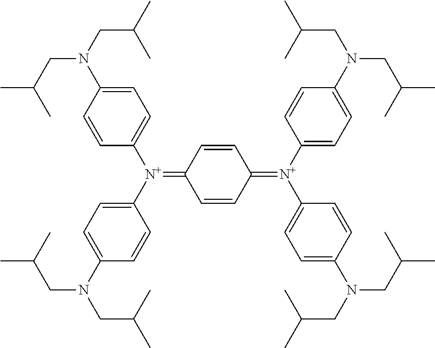 [SMILES: CC(C)CN(CC(C)C)c1ccc([N+](=C2C=CC(=[N+](c3ccc(N(CC(C)C)CC(C)C)cc3)c3ccc(N(CC(C)C)CC(C)C)cc3)C=C2)c2ccc(N(CC(C)C)CC(C)C)cc2)cc1] | (X-21) | 2 |
| (s-106) | 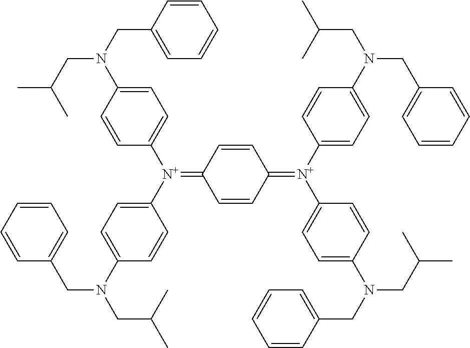 [SMILES: CC(C)CN(Cc1ccccc1)c1ccc([N+](=C2C=CC(=[N+](c3ccc(N(Cc4ccccc4)CC(C)C)cc3)c3ccc(N(Cc4ccccc4)CC(C)C)cc3)C=C2)c2ccc(N(Cc3ccccc3)CC(C)C)cc2)cc1] | (X-22) | 2 |
| (s-107) | 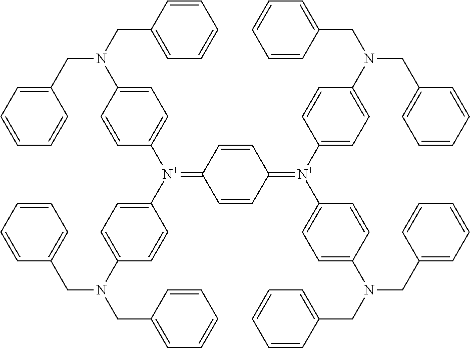 [SMILES: C1=CC(=[N+](c2ccc(N(Cc3ccccc3)Cc3ccccc3)cc2)c2ccc(N(Cc3ccccc3)Cc3ccccc3)cc2)C=CC1=[N+](c1ccc(N(Cc2ccccc2)Cc2ccccc2)cc1)c1ccc(N(Cc2ccccc2)Cc2ccccc2)cc1] | (X-24) | 2 |
| (s-108) | 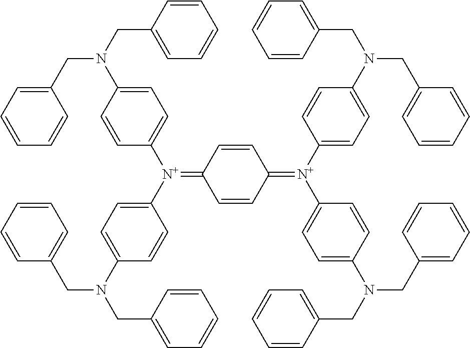 [SMILES: C1=CC(=[N+](c2ccc(N(Cc3ccccc3)Cc3ccccc3)cc2)c2ccc(N(Cc3ccccc3)Cc3ccccc3)cc2)C=CC1=[N+](c1ccc(N(Cc2ccccc2)Cc2ccccc2)cc1)c1ccc(N(Cc2ccccc2)Cc2ccccc2)cc1] | (X-28) | 2 |
| (s-109) | 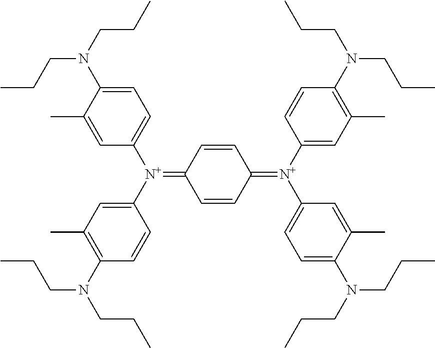 [SMILES: CCCN(CCC)c1ccc([N+](=C2C=CC(=[N+](c3ccc(N(CCC)CCC)c(C)c3)c3ccc(N(CCC)CCC)c(C)c3)C=C2)c2ccc(N(CCC)CCC)c(C)c2)cc1C] | (X-19) | 1 |
| (s-110) | 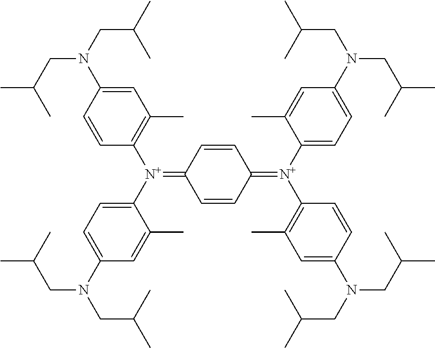 [SMILES: Cc1cc(N(CC(C)C)CC(C)C)ccc1[N+](=C1C=CC(=[N+](c2ccc(N(CC(C)C)CC(C)C)cc2C)c2ccc(N(CC(C)C)CC(C)C)cc2C)C=C1)c1ccc(N(CC(C)C)CC(C)C)cc1C] | (X-21) | 2 |
| (s-111) | 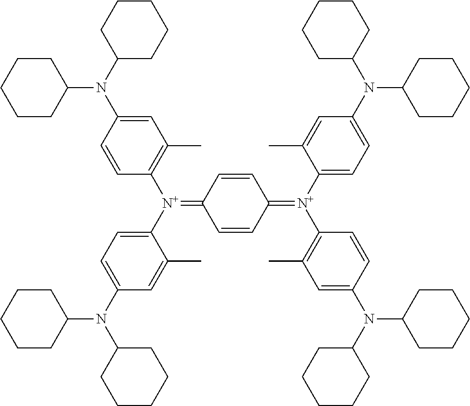 [SMILES: Cc1cc(N(C2CCCCC2)C2CCCCC2)ccc1[N+](=C1C=CC(=[N+](c2ccc(N(C3CCCCC3)C3CCCCC3)cc2C)c2ccc(N(C3CCCCC3)C3CCCCC3)cc2C)C=C1)c1ccc(N(C2CCCCC2)C2CCCCC2)cc1C] | (X-23) | 2 |
| (s-112) | 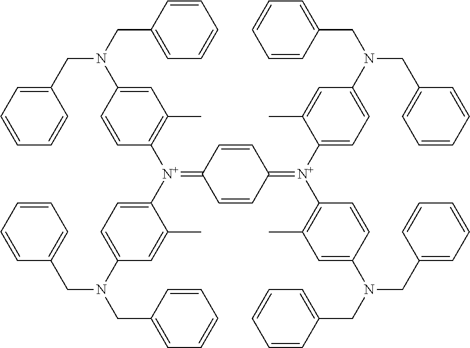 [SMILES: Cc1cc(N(Cc2ccccc2)Cc2ccccc2)ccc1[N+](=C1C=CC(=[N+](c2ccc(N(Cc3ccccc3)Cc3ccccc3)cc2C)c2ccc(N(Cc3ccccc3)Cc3ccccc3)cc2C)C=C1)c1ccc(N(Cc2ccccc2)Cc2ccccc2)cc1C] | (X-24) | 2 |
| (s-113) | 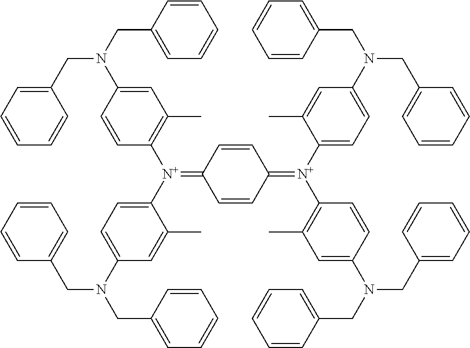 [SMILES: Cc1cc(N(Cc2ccccc2)Cc2ccccc2)ccc1[N+](=C1C=CC(=[N+](c2ccc(N(Cc3ccccc3)Cc3ccccc3)cc2C)c2ccc(N(Cc3ccccc3)Cc3ccccc3)cc2C)C=C1)c1ccc(N(Cc2ccccc2)Cc2ccccc2)cc1C] | (X-28) | 2 |

TABLE 6

| Anion | Structure |
|---|---|
| (X-1) | Cl⁻ |
| (X-2) | F⁻ |
| (X-3) | Br⁻ |
| (X-4) | PF₆ ⁻ |
| (X-5) | ClO₄⁻ |
| (X-6) | NO₃⁻ |
| (X-7) | BF₄⁻ |
| (X-8) | SCN⁻ |
| (X-9) | 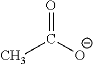 |
| (X-10) | 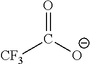 |
| (X-11) | 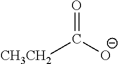 |
| (X-12) | 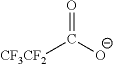 |
| (X-13) | 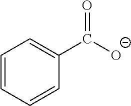 |
| (X-14) | 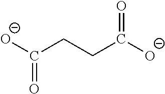 |
| (X-15) | 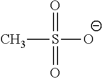 |
| (X-16) | 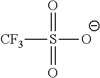 |
| (X-17) | 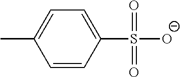 |
| (X-18) | 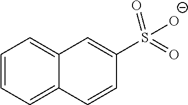 [SMILES: O=S(=O)([O-])c1ccc2ccccc2c1] |
| (X-19) | 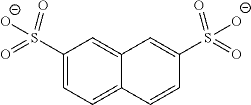 [SMILES: O=S(=O)([O-])c1ccc2ccc(S(=O)(=O)[O-])cc2c1] |
| (X-20) | 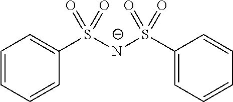 [SMILES: O=S(=O)([N-]S(=O)(=O)c1ccccc1)c1ccccc1] |
| (X-21) | 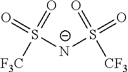 [SMILES: O=S(=O)([N-]S(=O)(=O)C(F)(F)F)C(F)(F)F] |
| (X-22) | 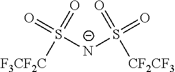 |
| (X-23) | 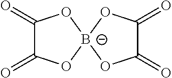 [SMILES: O=C1O[B-]2(OC1=O)OC(=O)C(=O)O2] |
| (X-24) | 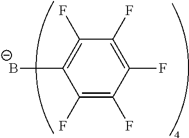 |
| (X-25) | 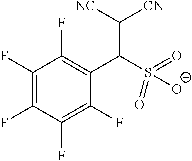 [SMILES: N#CC(C#N)C(c1c(F)c(F)c(F)c(F)c1F)S(=O)(=O)[O-]] |
| (X-26) | 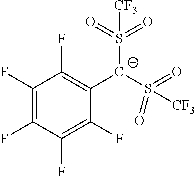 [SMILES: O=S(=O)([C-](c1c(F)c(F)c(F)c(F)c1F)S(=O)(=O)C(F)(F)F)C(F)(F)F] |
| (X-27) | 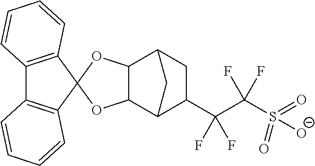 [SMILES: O=S(=O)([O-])C(F)(F)C(F)(F)C1CC2CC1C1OC3(OC21)c1ccccc1-c1ccccc13] |
| (X-28) | 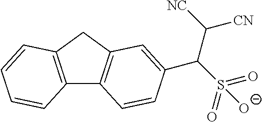 [SMILES: N#CC(C#N)C(c1ccc2c(c1)Cc1ccccc1-2)S(=O)(=O)[O-]] |

The compound (S) may be used singly or in combination of plural kinds thereof. When the compound is used singly, an optical filter excellent in cost can be obtained, and when the compound is used in combination of plural kinds thereof, an optical filter excellent in near-infrared cutting performance can be obtained. In particular, the following combination use: the compound (S) is used as a combination of at least one having an absorption maximum in the wavelength region of 600 to 750 nm and at least one having an absorption maximum in the wavelength region of 800 to 1150 nm; is preferable because a wide viewing angle, excellent color reproducibility and near-infrared cutting performance, and furthermore the effect of suppressing ghost in imaging of a light source under a dark environment are achieved.

For example, when a base material formed of a transparent resin substrate (ii) containing the compound (S) and the antioxidant (P), or a base material in which a resin layer containing the antioxidant (P) is laminated on a transparent resin substrate (iii) containing the compound (S) is used as the base material (i), the content per one kind of the compound (S) is preferably 0.001 to 2.0 parts by weight, more preferably 0.002 to 1.5 parts by weight, particularly preferably 0.003 to 1.0 part by weight based on 100 parts by weight of the transparent resin forming the transparent resin layer containing the compound (S). For example, when a base material in which a transparent resin layer containing the compound (S) and the antioxidant (P) is laminated on a glass support or a resin support that becomes a base, or a base material in which a resin layer containing the compound (S) is laminated on a transparent resin substrate (iv) containing the antioxidant (P) is used as the base material (i), the content per one kind of the compound (S) is preferably 0.1 to 5.0 parts by weight, more preferably 0.2 to 4.0 parts by weight, particularly preferably 0.3 to 3.0 parts by weight based on 100 parts by weight of the transparent resin forming the transparent resin layer containing the antioxidant (P). When the content of the compound (S) is the above ranges, an optical filter having good near-infrared absorption properties and a high visible light transmittance that are compatible with one another can be obtained.

<Antioxidant (P)>

The antioxidant (P) for use in the present invention is not specifically restricted provided that it is an antioxidant having at least one phosphorus atom in a molecule, but the antioxidant is preferably a compound having a structure represented by the following formula (p), more preferably at least one compound selected from compounds represented by the following formulae (I) to (III), further preferably any compound represented by the following formulae (p-1) to (p-4). The “antioxidant” in the present invention refers to various compounds having the property of preventing or suppressing oxidization caused under room-temperature or high-temperature conditions.

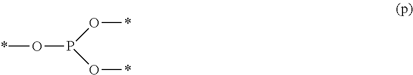 [SMILES: *OP(O*)O*]

In the formula (p), * represents a bond.

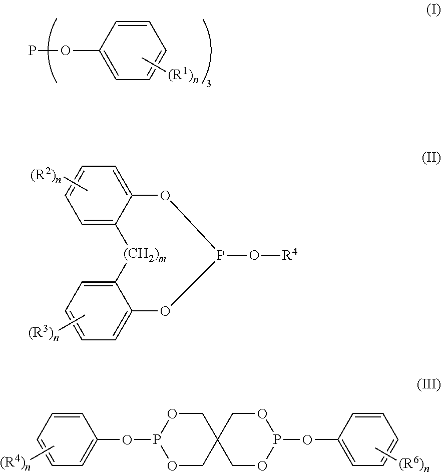

In the formulae (I) to (III), R¹ to R⁵ are each independently a hydrogen atom; a halogen atom; a substituted or unsubstituted hydrocarbon group of 1 to 30 carbon atoms, which may have a linking group containing an oxygen atom, a sulfur atom, a nitrogen atom or a silicon atom; or a polar group, n is an integer of 0 to 5, and m is 0 or 1.

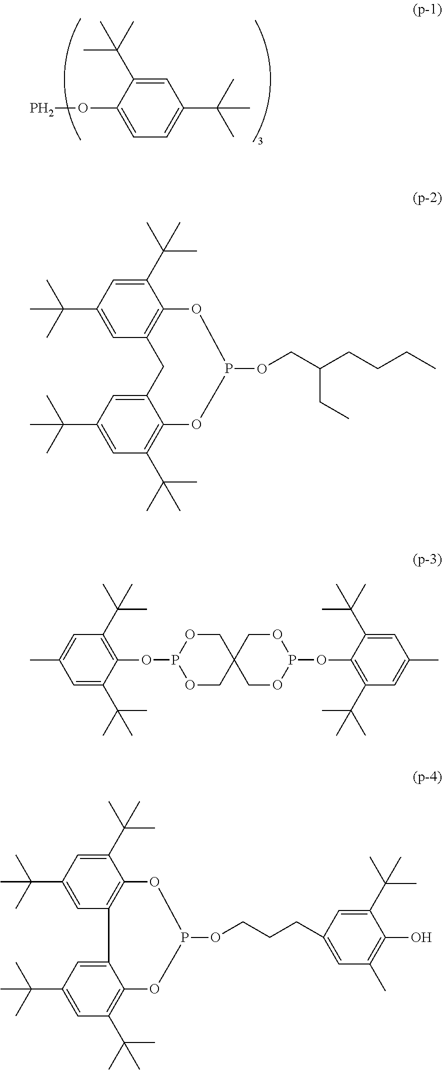

In particular, an antioxidant (P) having the above structure is preferable because of being capable of effectively suppressing decomposition of the compound (S) due to oxidization during a heating process such as a drying step in the production of the optical filter or under a usage environment of the optical filter.

The residual rate (Sr) of the compound (S), here calculated based on the spectral transmittance (Ta) of the base material (i) after drying at the second stage (100° C./8 hours under reduced pressure) and the spectral transmittance (Tb) of the base material (i) after drying at the fourth stage in any conditions of drying conditions (1) to (3) described in Examples and the like, is preferably not less than 80%, still more preferably not less than 85%, particularly preferably not less than 90%. When the residual rate (Sr) of the compound (S) is in the above ranges, an optical filter which has not only a high visible light transmittance, but also high light cut characteristics in the near-infrared wavelength region can be obtained even after the above drying. The residual rate (Sr) of the compound (S) after the drying can be calculated according to the following formula.

(Ta)′=(Ta)×100/(Tr)

(Tb)′=(Tb)×100/(Tr)

(Tr): external transmittance at absorption maximum wavelength, of base material singly formed of resin

(Aa)=−log{(Ta)′/100}

(Ab)=−log{(Ta)′/100}

log: common logarithm

(Sr)={(Ab)/(Aa)}×100

(Ta) and (Tb) mean the respective transmittances at an absorption maximum wavelength of 600 nm to 1150 nm, of the compound (S), at the above drying stages. If two or more absorption maximum wavelengths are here present in the region of 600 nm to 1150 nm, the transmittance at the absorption maximum wavelength on the longest wavelength side is used for the calculation. The transmittance (Tb) is preferably not more than 80%, still more preferably not more than 70%, particularly preferably not more than 60%.

The melting point of the antioxidant (P) is not specifically restricted provided that it is not lower than 100° C., but the melting point is preferably 100 to 300° C., more preferably 100 to 250° C., particularly preferably 100 to 200° C. If the melting point of the antioxidant is not lower than 300° C., the molecular weight is increased and the effect of heat resistance exerted in use of the same part(s) by weight of the antioxidant is deteriorated.

The content of the antioxidant (P) is preferably 0.1 to 3.0 parts by weight, still more preferably 0.1 to 2.0 parts by weight, particularly preferably 0.1 to 1.0 part by weight based on 100 parts by weight of the transparent resin.

The melting point and the content of the antioxidant (P), which are in the above ranges, can be preferable because the variation in the glass transition temperature (Tg) of the (transparent) resin layer can be suppressed. The variation width (Tg1-Tg2) between the original glass transition temperature (Tg1) of the transparent resin constituting the base material (i) and the glass transition temperature (Tg2) of the base material (i) containing the antioxidant (P) and the like is preferably 0 to 20° C., still more preferably 0 to 10° C., particularly preferably 0° C. to 5° C.

<Transparent Resin>

The transparent resin layer laminated on a resin support or a glass support and the transparent resin substrates (ii) to (iv) can be formed using a transparent resin.

The transparent resins may be used singly or two or more kinds for the base material (i).

The transparent resin is not specifically restricted as long as it does not impair the effect of the present invention. However, in order to form a film which ensures thermal stability and moldability into a film and on which a dielectric multilayer film can be formed through high-temperature deposition that is carried out at a deposition temperature of not lower than 100° C., there can be mentioned a resin preferably having a glass transition temperature (Tg) of 110 to 380° C., more preferably 110 to 370° C., still more preferably 120 to 360° C. Further, when the glass transition temperature of the resin is not lower than 140° C., a film on which a dielectric multilayer film can be formed by deposition at a higher temperature is obtained, so that such a resin is particularly preferable.

As the transparent resin, a resin such that when a resin plate having a thickness of 0.1 mm is formed from the resin, the total light transmittance (JIS K7105) of the resin plate preferably becomes 75 to 95%, still more preferably 78 to 95%, particularly preferably 80 to 95%, can be used. When a resin having the total light transmittance in such a range is used, the resulting substrate exhibits good transparency as an optical film.

The weight-average molecular weight (Mw) of the transparent resin, as measured by gel permeation chromatography (GPC) method, is usually 15,000 to 350,000, preferably 30,000 to 250,000, in terms of polystyrene, and the number-average molecular weight (Mn) thereof is usually 10,000 to 150,000, preferably 20,000 to 100,000, in terms of polystyrene.

Examples of the transparent resins include cyclic (poly)olefin-based resins, aromatic polyether-based resins, polyimide-based resins, fluorene polycarbonate-based resins, fluorene polyester-based resins, polycarbonate-based resins, polyamide (aramid)-based resins, polyarylate-based resins, polysulfone-based resins, polyether sulfone-based resins, polyparaphenylene-based resins, polyamideimide-based resins, polyethylene naphthalate (PEN)-based resins, fluorinated aromatic polymer-based resins, (modified) acrylic-based resins, epoxy-based resins, allyl ester-based curable resins, silsesquioxane-based ultraviolet curable resins, acrylic-based ultraviolet curable resins and vinyl-based ultraviolet curable resins.

<<Cyclic (Poly)Olefin-Based Resin>>

The cyclic (poly)olefin-based resin is preferably a resin obtained from at least one monomer selected from the group consisting of a monomer represented by the following formula (X₀) and a monomer represented by the following formula (Y₀), or a resin obtained by hydrogenating the resin thus obtained.

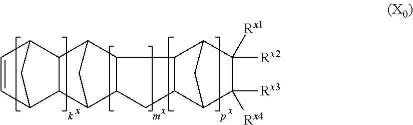

In the formula (X₀), R^{x1} to R^{x4} are each independently an atom or a group selected from the following (i′) to (ix′), and k^{x}, m^{x} and p^{x} are each independently 0 or a positive integer.

(i′) a hydrogen atom

(ii′) a halogen atom

(iii′) a trialkylsilyl group

(iv′) a substituted or unsubstituted hydrocarbon group of 1 to 30 carbon atoms, which has a linking group containing an oxygen atom, a sulfur atom, a nitrogen atom or a silicon atom

(v′) a substituted or unsubstituted hydrocarbon group of 1 to 30 carbon atoms

(vi′) a polar group (except (iv′))

(vii′) an alkylidene group formed by bonding of R^{x1} and R^{x2} or R^{x3} and R^{x4} to each other (R^{x1} to R^{x4} which do not take part in the bonding are each independently an atom or a group selected from the above (i′) to (vi′).)

(viii′) a monocyclic or polycyclic hydrocarbon ring or heterocyclic ring formed by bonding of R^{x1} and R^{x2} or R^{x3} and R^{x4} to each other (R^{x1} to R^{x4} which do not take part in the bonding are each independently an atom or a group selected from the above (i′) to (vi′).)

(ix′) a monocyclic hydrocarbon ring or heterocyclic ring formed by bonding of R^{x2} and R^{x3} to each other (R^{x1} and R^{x4} which do not take part in the bonding are each independently an atom or a group selected from the above (i′) to (vi′).)

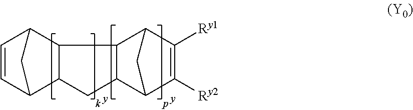

In the formula (Y₀), R^{y1} and R^{y2} are each independently an atom or a group selected from the aforesaid (i′) to (vi′) or represent a monocyclic or polycyclic alicyclic hydrocarbon, aromatic hydrocarbon or heterocyclic ring, which is formed by bonding of R^{y1} and R^{y2} to each other, and k^{y} and p^{y} are each independently 0 or a positive integer.

<<Aromatic Polyether-Based Resin>>

The aromatic polyether-based resin preferably has at least one structural unit selected from the group consisting of a structural unit represented by the following formula (1) and a structural unit represented by the following formula (2).

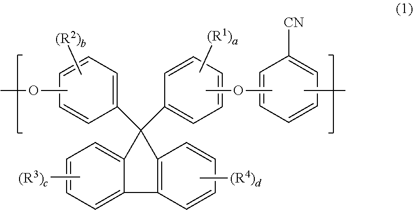

In the formula (1), R¹ to R⁴ are each independently a monovalent organic group of 1 to 12 carbon atoms, and “a” to “d” are each independently an integer of 0 to 4.

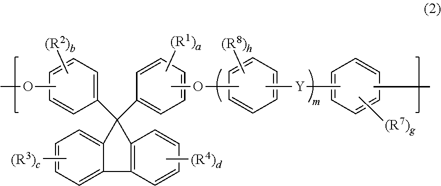

In the formula (2), R¹ to R⁴ and “a” to “d” have the same meanings as those of R¹ to R⁴ and “a” to “d” in the formula (1), respectively, Y is a single bond, —SO₂— or >C═O, R⁷ and R⁸ are each independently a halogen atom, a monovalent organic group of 1 to 12 carbon atoms or a nitro group, “g” and “h” are each independently an integer of 0 to 4, and “m” is 0 or 1, but when “m” is 0, R⁷ is not a cyano group.

Further, the aromatic polyether-based resin preferably has at least one structural unit selected from the group consisting of a structural unit represented by the following formula (3) and a structural unit represented by the following formula (4).

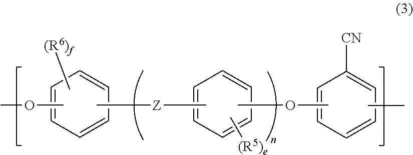

In the formula (3), R⁵ and R⁶ are each independently a monovalent organic group of 1 to 12 carbon atoms, Z is a single bond, —O—, —S—, —SO₂—, >C═O, —CONH—, —COO— or a divalent organic group of 1 to 12 carbon atoms, “e” and “f” are each independently an integer of 0 to 4, and “n” is 0 or 1.

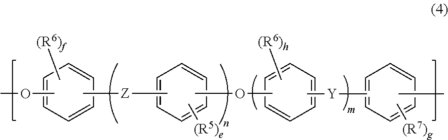

In the formula (4), R⁷, R⁸, Y, “m”, “g” and “h” have the same meanings as those of R⁷, R⁸, Y, “m”, “g” and “h” in the formula (2), respectively, and R⁵, R⁶, Z, “n”, “e” and “f” have the same meanings as those of R⁵, R⁶, Z, “n”, “e” and “f” in the formula (3), respectively.

<<Polyimide-Based Resin>>

The polyimide-based resin is not specifically restricted provided that it is a high-molecular compound containing an imide linkage in a repeating unit, and it can be synthesized by a process described in, for example, Japanese Patent Laid-Open Publication No. 2006-199945 or Japanese Patent Laid-Open Publication No. 2008-163107.

<<Fluorene Polycarbonate-Based Resin>>

The fluorene polycarbonate-based resin is not specifically restricted provided that it is a polycarbonate resin containing a fluorene moiety, and it can be synthesized by a process described in, for example, Japanese Patent Laid-Open Publication No. 2008-163194.

<<Fluorene Polyester-Based Resin>>

The fluorene polyester-based resin is not specifically restricted provided that it is a polyester resin containing a fluorene moiety, and it can be synthesized by a process described in, for example, Japanese Patent Laid-Open Publication No. 2010-285505 or Japanese Patent Laid-Open Publication No. 2011-197450.

<<Fluorinated Aromatic Polymer-Based Resin>>

The fluorinated aromatic polymer-based resin is not specifically restricted, but it is preferably a polymer containing an aromatic ring having at least one fluorine atom and a repeating unit containing at least one linkage selected from the group consisting of an ether linkage, a ketone linkage, a sulfone linkage, am amide linkage, an imide linkage and an ester linkage, and it can be synthesized by a process described in, for example, Japanese Patent Laid-Open Publication No. 2008-181121.

<<Acrylic-Based Ultraviolet Curing Resin>>

The acrylic-based ultraviolet curing resin is not specifically restricted, but there can be mentioned a resin synthesized from a resin composition containing a compound having one or more acrylic groups or methacrylic groups in a molecule and a compound that is decomposed by ultraviolet rays to generate an active radical. When a base material in which a transparent resin layer containing the compound (S) and a curable resin is laminated on a glass support or a resin support that becomes a base or a base material in which a resin layer such as an overcoat layer formed from a curable resin, etc. is laminated on the transparent resin substrate (ii) containing the compound (S) is used as the base material (i), the acrylic-based ultraviolet curing resin is particularly preferably used as the curable resin.

<<Commercial Products>>

As commercial products of the transparent resins, the following commercial products, etc. can be mentioned. Examples of commercial products of the cyclic (poly)olefin-based resins include Arton available from JSR Corporation, ZEONOR available from Zeon Corporation, APEL available from Mitsui Chemicals, Inc. and TOPAS available from Polyplastics Co., Ltd. Examples of commercial products of the polyether sulfone-based resins include Sumika Excel PES available from Sumitomo Chemical Co., Ltd. Examples of commercial products of the polyimide-based resins include Neopulim L available from Mitsubishi Gas Chemical Company Inc. Examples of commercial products of the polycarbonate-based resins include PURE-ACE available from Teijin Ltd. Examples of commercial products of the fluorene polycarbonate-based resins include Lupizeta EP-5000 available from Mitsubishi Gas Chemical Company Inc. Examples of commercial products of the fluorene polyester-based resins include OKP4HT available from Osaka Gas Chemicals Co., Ltd. Examples of commercial products of the acrylic-based resins include ACRYVIEWA available from Nippon Shokubai Co., Ltd. Examples of commercial products of the silsesquioxane-based ultraviolet curing resins include Silplus available from Shin-Nittetsu Chemical Co., Ltd.

<Other Components>

The base material (i) may further contain additives, such as near-ultraviolet absorbing agent, antioxidant (Q) other than the antioxidant (P), fluorescence quencher and metal complex-based compound, as other components, within limits not detrimental to the effect of the present invention. These other components may be used singly or two or more kinds.

Examples of the near-ultraviolet absorbing agents include an azomethine-based compound, an indole-based compound, a benzotriazole-based compound and a triazine-based compound.

The antioxidant (Q) is not specifically restricted as long as it is not an antioxidant (P) having at least one phosphorus atom in a molecule, and examples include compounds represented by the following formulae (q-1) to (q-3). A compound represented by the following formula (q-1) is particularly preferable.

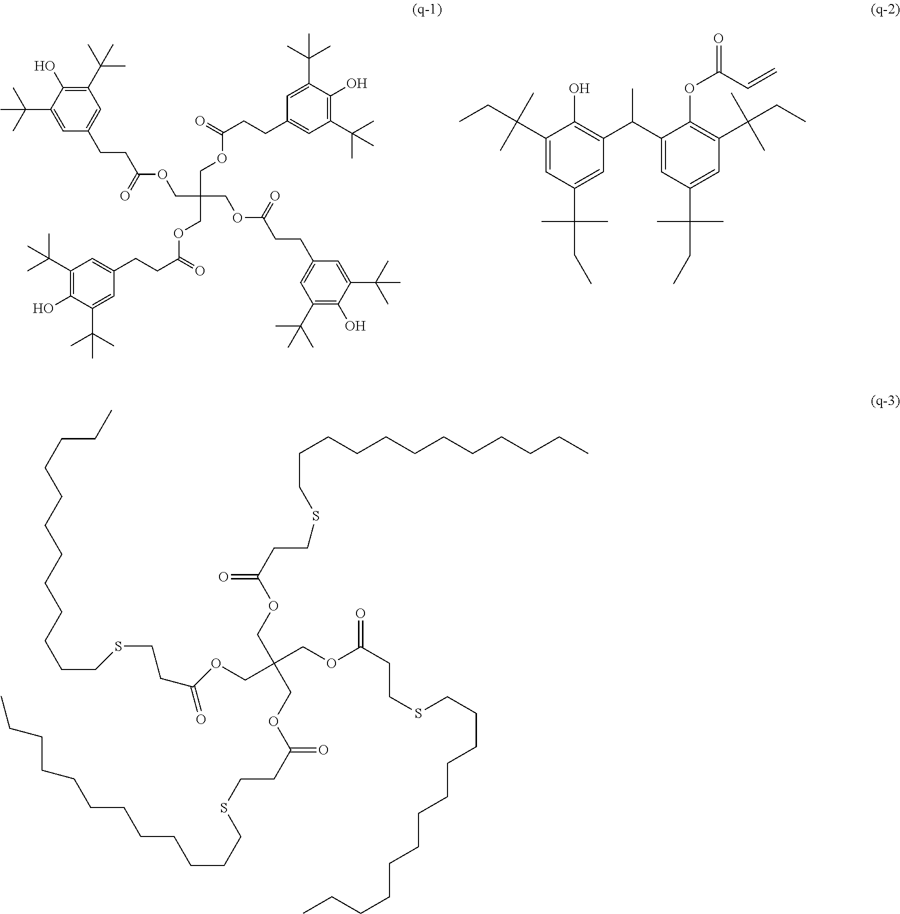 [SMILES: CC(C)(C)c1cc(CCC(=O)OCC(COC(=O)CCc2cc(C(C)(C)C)c(O)c(C(C)(C)C)c2)(COC(=O)CCc2cc(C(C)(C)C)c(O)c(C(C)(C)C)c2)COC(=O)CCc2cc(C(C)(C)C)c(O)c(C(C)(C)C)c2)cc(C(C)(C)C)c1O ; C=CC(=O)Oc1c(C(C)c2cc(C(C)(C)CC)cc(C(C)(C)CC)c2O)cc(C(C)(C)CC)cc1C(C)(C)CC ; CCCCCCCCCCCCSCCC(=O)OCC(COC(=O)CCSCCCCCCCCCCCC)(COC(=O)CCSCCCCCCCCCCCC)COC(=O)CCSCCCCCCCCCCCC]

These additives may be mixed together with a resin, etc. in the production of the base material (i), or they may be added when a resin is synthesized. Although the amount of such an additive is properly selected according to the desired properties, it is usually 0.1 to 3.0 parts by weight, preferably 0.1 to 2.0 parts by weight, particularly preferably 0.1 to 1.0 part by weight, based on 100 parts by weight of the resin.

<Production Process for Base Material (i)>

When the base material (i) is a base material including any of the transparent resin substrates (ii) to (iv), the transparent resin substrates (ii) to (iv) can be each formed by, for example, melt molding or cast molding, and if necessary, after molding, the molded product is coated with coating agents, such as an antireflection agent, a hard coating agent and/or an antistatic agent, whereby a base material in which an overcoat layer has been laminated on the substrate can be produced.

When the base material (i) is a base material in which a transparent resin layer such as an overcoat layer formed from a curable resin containing the compound (S) and the antioxidant (P) is laminated on a glass support or a resin support that becomes a base, the base material in which a transparent resin layer is formed on a glass support or a resin support that becomes a base can be produced by, for example, subjecting a resin solution containing the compound (S) and the antioxidant (P) to melt molding or cast molding on a glass support or a resin support that becomes a base, preferably by coating through a method of spin coating, slit coating, ink jetting or the like, then removing the solvent by drying, and if necessary, further carrying out light irradiation or heating.

<<Melt Molding>>

As the melt molding, there can be specifically mentioned a method of melt-molding pellets obtained by melt-kneading a resin, the compound (S), the antioxidant (P), etc.; a method of melt-molding a resin composition containing a resin, the compound (S) and the antioxidant (P); a method of melt-molding pellets obtained by removing a solvent from a resin composition containing the compound (S), the antioxidant (P), a resin and a solvent; or the like. Examples of the melt molding methods include injection molding, melt extrusion molding and blow molding.

<<Cast Molding>>

The base material can be also produced by the cast molding, specifically by a method comprising casting a resin composition containing the compound (S), the antioxidant (P), a resin and a solvent onto an appropriate support and removing the solvent; a method comprising casting a curable composition containing the compound (S), the antioxidant (P), a photo-curing resin and/or a thermosetting resin onto an appropriate support, removing the solvent and then curing the composition by an appropriate means such as ultraviolet irradiation or heating; or the like.

When the base material (i) is a base material formed of the transparent resin substrate (ii) containing the compound (S) and the antioxidant (P), the base material (i) can be obtained by performing cast molding and thereafter peeling the coating film from a support. When the base material (i) is a base material in which a transparent resin layer such as an overcoat layer formed from a curable resin containing the compound (S) and the antioxidant (P) is laminated on a support such as a glass support or a resin support that becomes a base, the base material (i) can be obtained without peeling the coating film after cast molding.

Examples of the supports include a glass plate, a steel belt, a steel drum and a transparent resin support (e.g., a polyester film and a cyclic olefin-based resin film).

Further, the transparent resin layer can be also formed directly on an optical part by a process comprising coating an optical part made of a glass plate, quartz, transparent plastic or the like with the aforesaid resin composition and drying the solvent, a process comprising coating the optical part with the aforesaid curable composition, curing and drying the composition, or the like.

The amount of a residual solvent in the transparent resin layer (transparent resin substrate (ii)) obtained by the above method is preferably as small as possible. Specifically, the amount of the residual solvent is preferably not more than 3% by weight, more preferably not more than 1% by weight, still more preferably not more than 0.5% by weight, based on the weight of the transparent resin layer (transparent resin substrate (ii)). When the amount of the residual solvent is in the above range, a transparent resin layer (transparent resin substrate (ii)) that is rarely deformed or rarely changed in properties and can easily exert a desired function is obtained.

[Dielectric Multilayer Film]

As the dielectric multilayer film, a dielectric multilayer film in which high-refractive index material layers and low-refractive index material layers are alternately laminated can be mentioned. As the material to form the high-refractive index material layers, a material having a refractive index of not less than 1.7 can be used, and a material having a refractive index in the range of 1.7 to 2.5 is usually selected. Such a material is, for example, a material containing titanium oxide, zirconium oxide, tantalum pentoxide, niobium pentoxide, lanthanum oxide, yttrium oxide, zinc oxide, zinc sulfide or indium oxide as a main component and containing titanium oxide, tin oxide and/or cerium oxide in a small amount (e.g., 0 to 10% by weight based on the main component).

As the material to form the low-refractive index material layer, a material having a refractive index of not more than 1.6 can be used, and a material having a refractive index in the range of 1.2 to 1.6 is usually selected. Examples of such materials include silica, alumina, lanthanum fluoride, magnesium fluoride and aluminum sodium hexafluoride.

The method for laminating the high-refractive index material layer and the low-refractive index material layer is not specifically restricted as far as a dielectric multilayer film wherein these material layers are laminated is formed. For example, the dielectric multilayer film can be formed by alternately laminating the high-refractive index material layer and the low-refractive index material layer directly on the substrate (i) through CVD method, sputtering method, vacuum deposition method, ion-assisted deposition method, ion plating method or the like.

When the near-infrared wavelength to be cut is taken as λ (nm), the thickness of each layer of the high-refractive index material and the low-refractive index material is preferably 0.1λ to 0.5λ. The value of λ (nm) is, for example, 700 to 1400 nm, preferably 750 to 1300 nm. When the thickness is in this range, the optical film thickness calculated as a product (n×d) of the refractive index (n) and the film thickness (d), which is λ/4, and the thickness of each layer of the high-refractive index material and the low-refractive index material become almost the same as each other, and from the relationship between the optical properties of reflection and refraction, cutting/transmission of a specific wavelength tends to be able to be easily controlled.

The total number of the high-refractive index material layers and the low-refractive index material layers laminated in the dielectric multilayer film is preferably 16 to 70, more preferably 20 to 60, in the whole optical filter. When the thickness of each layer, the thickness of the dielectric multilayer film and the total number of lamination layers in the whole optical filter are in the above ranges, sufficient manufacturing margin can be ensured, and moreover, warpage of the optical filter and cracks of the dielectric multilayer film can be reduced.

In the present invention, by properly selecting the material species to constitute the high-refractive index material layers and the low-refractive index material layers, the thickness of each layer of the high-refractive index material layers and the low-refractive index material layers, the order of laminating, and the number of lamination layers in accordance with absorption properties of the compound (S), an optical filter having sufficient light cut characteristics in the near-infrared wavelength region can be obtained while ensuring a sufficient transmittance in the visible region.

[Other Functional Films]

In the optical filter of the present invention, for the purpose of, for example, enhancing surface hardness of the base material (i) or the dielectric multilayer film, enhancing chemical resistance, preventing static electrification and removing flaws, functional films, such as an antireflection film, a hard coating film and an antistatic film, can be provided, as appropriate in such a manner that the effects of the present invention are not adversely affected, between the base material (i) and the dielectric multilayer film, on a surface of the base material (i) opposite to the surface where the dielectric multilayer film has been provided or on a surface of the dielectric multilayer film opposite to the surface where the base material (i) has been provided.

[Uses of Optical Filter]

The optical filter of the present invention has excellent durable performance and has excellent near-infrared cutting ability. Therefore, the optical filter is useful for correction of visibility of a sold-state imaging element, such as a CCD or CMOS image sensor of a camera module. In particular, the optical filter is useful for digital still camera, camera for smartphone, camera for cellular phone, digital video camera, camera for wearable device, PC camera, surveillance camera, camera for automobile, TV, car navigation system, personal digital assistant, video game console, handheld game console, fingerprint authentication system, digital music player, etc. Moreover, the optical filter is useful also as a heat ray cut filter mounted on glass plate of an automobile, building or the like.

[Solid-State Image Pickup Device]

The solid-state image pickup device of the present invention is equipped with the optical filter of the present invention. Here, the solid-state image pickup device is an image sensor having a solid-state image sensor, such as a CCD or CMOS image sensor, and is specifically used for digital still camera, camera for a smartphone, camera for a cellular phone, camera for wearable device, digital video camera, etc. For example, the camera module of the present invention is equipped with the optical filter of the present invention.

### EXAMPLES

The present invention is more specifically described with reference to the following examples, but it should be construed that the present invention is in no way limited to those examples. The term “part(s)” means “part(s) by weight” unless otherwise noted. Methods for measuring property values and methods for evaluating properties are as follows.

<Molecular Weight>

Taking into consideration the solubility of each resin in a solvent, etc., a molecular weight of the resin was measured by the following method (a) or (b).

(a) Using a gel permeation chromatography (GPC) apparatus (150C type, column: H type column available from Tosoh Corporation, developing solvent: o-dichlorobenzene) manufactured by WATERS Corporation, a weight-average molecular weight (Mw) and a number-average molecular weight (Mn) in terms of standard polystyrene were measured.

(b) Using a GPC apparatus (HLC-8220 type, column: TSKgel α-M, developing solvent: THF) manufactured by Tosoh Corporation, a weight-average molecular weight (Mw) and a number-average molecular weight (Mn) in terms of standard polystyrene were measured.

With regard to the resin synthesized in the later-described Resin Synthesis Example 3, measurement of a molecular weight by the above method was not carried out, but measurement of an inherent viscosity by the following method (c) was carried out.

(c) A part of a polyimide resin solution was introduced into anhydrous methanol to precipitate a polyimide resin, and filtration was carried out to separate the resin from an unreacted monomer. Then, 0.1 g of polyimide obtained by vacuum drying the resulting resin at 80° C. for 12 hours was dissolved in 20 mL of N-methyl-2-pyrrolidone, and an inherent viscosity (μ) at 30° C. was determined using a Cannon-Fenske viscometer and the following formula.

μ={In(tₛ/t₀)}/C

t₀: flow time of solvent

tₛ: flow time of dilute polymer solution

C: 0.5 g/dL

<Glass Transition Temperature (Tg)>

Using a differential scanning calorimeter (DSC 6200) manufactured by SII Nanotechnology Inc., a glass transition temperature was measured at a heating rate of 20° C./min in a stream of nitrogen.

<Spectral Transmittance>

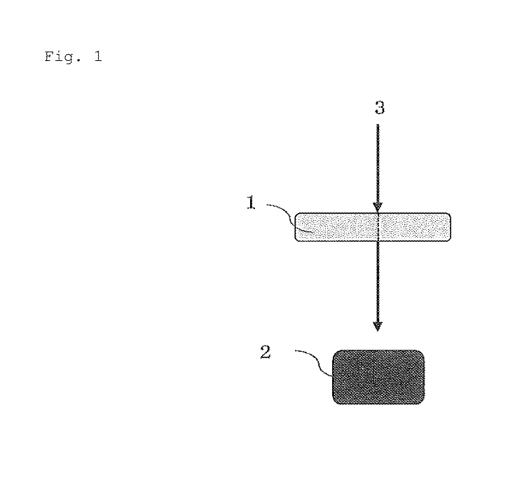

Using a spectrophotometer (U-4100) manufactured by Hitachi High-Technologies Corporation, (Ta) and (Tb) of a base material, and a transmittance of an optical filter in each wavelength region were measured. This transmittance was obtained by measuring a transmittance of light transmitted perpendicularly to the filter as shown in FIG. 1.

### Synthesis Examples

The compound (S) used in the following Examples was synthesized by a commonly known method. Examples of such commonly known methods include the methods described in Japanese Patent No. 3366697, Japanese Patent No. 2846091, Japanese Patent No. 2864475, Japanese Patent No. 3703869, Japanese Patent Laid-Open Publication No. 1985-228448, Japanese Patent Laid-Open Publication No. 1989-146846, Japanese Patent Laid-Open Publication No. 1989-228960, Japanese Patent No. 4081149, Japanese Patent Laid-Open Publication No. 1988-124054, “phthalocyanine-Chemistry and Functions” (IPC, 1997), Japanese Patent Laid-Open Publication No. 2007-169315, Japanese Patent Laid-Open Publication No. 2009-108267, Japanese Patent Laid-Open Publication No. 2010-241873, Japanese Patent No. 3699464, Japanese Patent No. 4740631 and Japanese Patent No. 5033632.

The antioxidant (P) used in the following Examples was a commercially available product, or was synthesized by a commonly known method. Examples of such common synthesis methods include the methods described in Japanese Patent Laid-Open Publication No. 1995-267971 and Japanese Patent Laid-Open Publication No. 1996-283280.

### Resin Synthesis Example 1

In a reaction container purged with nitrogen, 100 parts of 8-methyl-8-methoxycarbonyltetracyclo[4.4.0.1^{2,5}.1^{7,10}]dodeca-3-ene (also referred to as “DNM” hereinafter) represented by the following formula (a), 18 parts of 1-hexene (molecular weight modifier) and 300 parts of toluene (solvent for ring-opening polymerization reaction) were placed, and this solution was heated to 80° C. Then, to the solution in the reaction container, 0.2 part of a toluene solution of triethylaluminum (0.6 mol/liter) and 0.9 part of a toluene solution of methanol-modified tungsten hexachloride (concentration: 0.025 mol/liter) were added as polymerization catalysts, and the resulting solution was heated and stirred at 80° C. for 3 hours to perform ring-opening polymerization reaction, whereby a ring-opened polymer solution was obtained. The polymerization conversion ratio in this polymerization reaction was 97%.

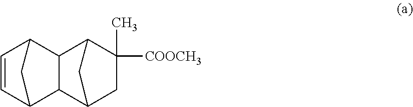 [SMILES: COC(=O)C1(C)CC2CC1C1C3C=CC(C3)C21]

In an autoclave, 1,000 parts of the ring-opened polymer solution obtained as above were placed, and to this ring-opened polymer solution, 0.12 parts of RuHCl(CO) [P(C₆H₅)₃]₃ was added, and they were heated and stirred for 3 hours under the conditions of a hydrogen gas pressure of 100 kg/cm² and a reaction temperature of 165° C. to perform hydrogenation reaction. After the resulting reaction solution (hydrogenated polymer solution) was cooled, the hydrogen gas pressure was released. This reaction solution was poured into a large amount of methanol, and the resulting precipitate was separated and recovered. Then, the precipitate was dried to obtain a hydrogenated polymer (also referred to as a “resin A” hereinafter). The resulting resin A had a number-average molecular weight (Mn) of 32,000, a weight-average molecular weight (Mw) of 137,000 and a glass transition temperature (Tg) of 165° C.

### Resin Synthesis Example 2

In a 3-liter four-neck flask, 35.12 g (0.253 mol) of 2,6-difluorobenzonitrile, 87.60 g (0.250 mol) of 9,9-bis(4-hydroxyphenyl)fluorene, 41.46 g (0.300 mol) of potassium carbonate, 443 g of N,N-dimethylacetamide (also referred to as “DMAc” hereinafter) and 111 g of toluene were placed. Subsequently, to the four-neck flask, a thermometer, a stirrer, a three-way cock with a nitrogen feed pipe, a Dean-Stark tube and a cooling pipe were fixed.

Then, the flask was purged with nitrogen. Thereafter, the resulting solution was subjected to reaction at 140° C. for 3 hours, and water produced was removed from the Dean-Stark tube whenever necessary. When production of water came to be not detected, the temperature was slowly raised up to 160° C., and the reaction was carried out at the same temperature for 6 hours.

After the reaction solution was cooled down to room temperature (25° C.), a salt produced was removed by a filter paper, then the filtrate was introduced into methanol to perform reprecipitation, and filtration was carried out to isolate a filter residue (residue). The resulting filter residue was vacuum dried at 60° C. for one night to obtain a white powder (also referred to as a “resin B” hereinafter) (yield: 95%). The resulting resin B had a number-average molecular weight (Mn) of 75,000, a weight-average molecular weight (Mw) of 188,000 and a glass transition temperature (Tg) of 285° C.

### Resin Synthesis Example 3

In a 500-mL five-neck flask equipped with a thermometer, a stirrer, a nitrogen feed pipe, a dropping funnel with a side tube, a Dean-Stark tube and a cooling pipe, 27.66 g (0.08 mol) of 1,4-bis(4-amino-α,α-dimethylbenzyl)benzene and 7.38 g (0.02 mol) of 4,4′-bis(4-aminophenoxy)biphenyl were placed in a stream of nitrogen, and they were dissolved in 68.65 g of γ-butyrolactone and 17.16 g of N,N-dimethylacetamide. The resulting solution was cooled to 5° C. using an ice water bath, and with maintaining the solution at the same temperature, 22.62 g (0.1 mol) of 1,2,4,5-cyclohexanetetracarboxylic dianhydride and 0.50 g (0.005 mol) of triethylamine as an imidization catalyst were added all together. After the addition was completed, the temperature was raised to 180° C., and with removing the distillate whenever necessary, the reaction solution was refluxed for 6 hours. After the reaction was completed, air cooling was carried out until the internal temperature became 100° C. Thereafter, 143.6 g of N,N-dimethylacetamide was added to dilute the reaction solution, and with stirring, the resulting solution was cooled to obtain 264.16 g of a polyimide resin solution having a solid concentration of 20% by weight. Apart of the polyimide resin solution was poured into 1 liter of methanol to precipitate polyimide. The polyimide was filtered off, washed with methanol and then dried for 24 hours in a vacuum dryer at 100° C. to obtain a white powder (also referred to as a “resin C” hereinafter). When an IR spectrum of the resulting resin C was measured, absorption at 1704 cm⁻¹ and 1770 cm⁻¹ characteristic of an imide group was observed. The resin C had a glass transition temperature (Tg) of 310° C., and the inherent viscosity measurement resulted in 0.87.

### Example 1

In Example 1, an optical filter comprising a base material (1) formed of a transparent resin substrate was prepared according to the following procedure and conditions.

In a container, 100 parts of the resin A obtained in Resin Synthesis Example 1, 0.005 parts of the compound (s-27) (absorption maximum wavelength in dichloromethane: 874 nm), 0.04 parts of the compound (s-60) (absorption maximum wavelength in dichloromethane: 703 nm) and 0.09 parts of the compound (s-76) (absorption maximum wavelength in dichloromethane: 736 nm), as the compound (S), 0.3 parts of the compound (p-1) (melting point: 180 to 190° C.) as the antioxidant (P), and methylene chloride were placed to prepare a solution having a resin concentration of 23% by weight. The resulting solution was cast onto a flat glass plate and dried at 20° C. for 8 hours, and then, the resulting coating film was peeled from the glass plate. The coating film thus peeled was further dried at 100° C. for 8 hours under reduced pressure to obtain a base material (1) formed of a transparent resin substrate having a thickness of 0.1 mm, a length of 60 mm and a width of 60 mm. A spectral transmittance of this base material (1) was measured, and (Ta) was determined. After the measurement, the base material was dried at 150° C. for 1 hour and furthermore at 200° C. for 15 minutes, thereafter a spectral transmittance of the base material (1) was again measured, and (Tb) and (Sr) were determined. The glass transition temperature of the base material (1) was also measured. The results are set forth in Table 11.

Subsequently, on one surface of the resulting base material (1), a dielectric multilayer film (I) was formed as a first optical layer, and on the other surface of the base material (1), a dielectric multilayer film (II) was formed as a second optical layer, whereby an optical filter having a thickness of about 0.104 mm was obtained. The dielectric multilayer film (I) was constituted of silica (SiO₂) layers and titania (TiO₂) layers that had been alternately laminated at a deposition temperature of 100° C. (total: 26 layers). The dielectric multilayer film (II) was constituted of silica (SiO₂) layers and titania (TiO₂) layers that had been alternately laminated at a deposition temperature of 100° C. (total: 20 layers). In each of the dielectric multilayer films (I) and (II), the silica layers and the titania layers were alternately laminated in the order of a titania layer, a silica layer, a titania layer, - - - a silica layer, a titania layer and a silica layer from the base material side, and the outermost layer of the optical filter was a silica layer.

Designing of the dielectric multilayer films (I) and (II) was carried out in the following manner.

The thickness of each layer and the number of layers were optimized according to the dependence of the base material refractive index on the wavelength and the absorption properties of the applied compound (S) so that the reflection prevention effect in the visible region and the selective transmission/reflection performance in the near-infrared region could be attained, by the use of optical thin film design software (Essential Macleod, available from Thin Film Center, Inc.). When optimization was carried out, input parameters (Target values) into the software in this Example were set as shown in the following Table 7.

TABLE 7

| | | Input parameter into software | | | |
|---|---|---|---|---|---|
| Dielectric | | | Re- | | |
| multilayer | Wavelength | Incident | quired | Target | |
| film | (nm) | Angle | Value | Tolerance | Type |
| (I) | 380 to 700 | 0 | 100 | 1 | Transmittance |
| | 705 to 900 | 0 | 0 | 1 | Transmittance |
| | 905 to 950 | 0 | 0 | 0.5 | Transmittance |
| (II) | 420 to 700 | 0 | 100 | 1 | Transmittance |
| | 970 to 1100 | 0 | 0 | 1 | Transmittance |
| | 1105 to 1220 | 0 | 0 | 0.5 | Transmittance |

As a result of optimization of film constitution, the dielectric multilayer film (I) became a multilayer deposited film of 26 lamination layers, the film being constituted of silica layers each having a film thickness of 31 to 157 nm and titania layers each having a film thickness of 11 to 95 nm alternately laminated and the dielectric multilayer film (II) became a multilayer deposited film of 20 lamination layers, the film being constituted of silica layers each having a film thickness of 38 to 199 nm and titania layers each having a film thickness of 12 to 117 nm alternately laminated, in Example 1. An example of the film constitution obtained by optimization is shown in Table 8.

TABLE 8

| Dielectric | | Film | Physical film | Optical film |
|---|---|---|---|---|
| multilayer film | Layer | material | thickness | thickness |
| (I) | 1 | SiO₂ | 78.0 | 0.205λ |
| | 2 | TiO₂ | 87.8 | 0.386λ |
| | 3 | SiO₂ | 154.1 | 0.405λ |
| | 4 | TiO₂ | 85.6 | 0.376λ |
| | 5 | SiO₂ | 149.4 | 0.393λ |
| | 6 | TiO₂ | 83.1 | 0.365λ |
| | 7 | SiO₂ | 147.4 | 0.388λ |
| | 8 | TiO₂ | 82.8 | 0.364λ |
| | 9 | SiO₂ | 147.1 | 0.387λ |
| | 10 | TiO₂ | 82.6 | 0.363λ |
| | 11 | SiO₂ | 147.0 | 0.387λ |
| | 12 | TiO₂ | 82.5 | 0.362λ |
| | 13 | SiO₂ | 147.2 | 0.387λ |
| | 14 | TiO₂ | 82.8 | 0.364λ |
| | 15 | SiO₂ | 146.9 | 0.386λ |
| | 16 | TiO₂ | 82.3 | 0.362λ |
| | 17 | SiO₂ | 147.6 | 0.388λ |
| | 18 | TiO₂ | 83.1 | 0.365λ |
| | 19 | SiO₂ | 146.9 | 0.386λ |
| | 20 | TiO₂ | 83.0 | 0.364λ |
| | 21 | SiO₂ | 150.7 | 0.396λ |
| | 22 | TiO₂ | 87.0 | 0.382λ |
| | 23 | SiO₂ | 156.9 | 0.413λ |
| | 24 | TiO₂ | 95.0 | 0.417λ |
| | 25 | SiO₂ | 31.2 | 0.082λ |
| | 26 | TiO₂ | 10.3 | 0.045λ |

Base material

| | | | | |
|---|---|---|---|---|
| (II) | 27 | TiO₂ | 11.8 | 0.052λ |
| | 28 | SiO₂ | 37.9 | 0.1λ |
| | 29 | TiO₂ | 117.1 | 0.514λ |
| | 30 | SiO₂ | 192.2 | 0.505λ |
| | 31 | TiO₂ | 113.5 | 0.498λ |
| | 32 | SiO₂ | 197.6 | 0.52λ |
| | 33 | TiO₂ | 116.7 | 0.513λ |
| | 34 | SiO₂ | 198.4 | 0.522λ |
| | 35 | TiO₂ | 115.9 | 0.509λ |
| | 36 | SiO₂ | 198.6 | 0.522λ |
| | 37 | TiO₂ | 116.1 | 0.51λ |
| | 38 | SiO₂ | 196.7 | 0.517λ |
| | 39 | TiO₂ | 114.0 | 0.501λ |
| | 40 | SiO₂ | 193.3 | 0.508λ |
| | 41 | TiO₂ | 110.6 | 0.486λ |
| | 42 | SiO₂ | 185.9 | 0.489λ |
| | 43 | TiO₂ | 106.0 | 0.466λ |
| | 44 | SiO₂ | 182.6 | 0.48λ |
| | 45 | TiO₂ | 105.2 | 0.462λ |
| | 46 | SiO₂ | 91.1 | 0.239λ |

*λ = 550 nm

A spectral transmittance measured in the perpendicular direction to the resulting optical filter was measured, and optical properties in each wavelength region were evaluated. The results are set forth in Table 11.

### Example 2

In Example 2, an optical filter comprising a base material (2) formed of a transparent resin substrate having resin layers on both surfaces was prepared according to the following procedure and conditions.

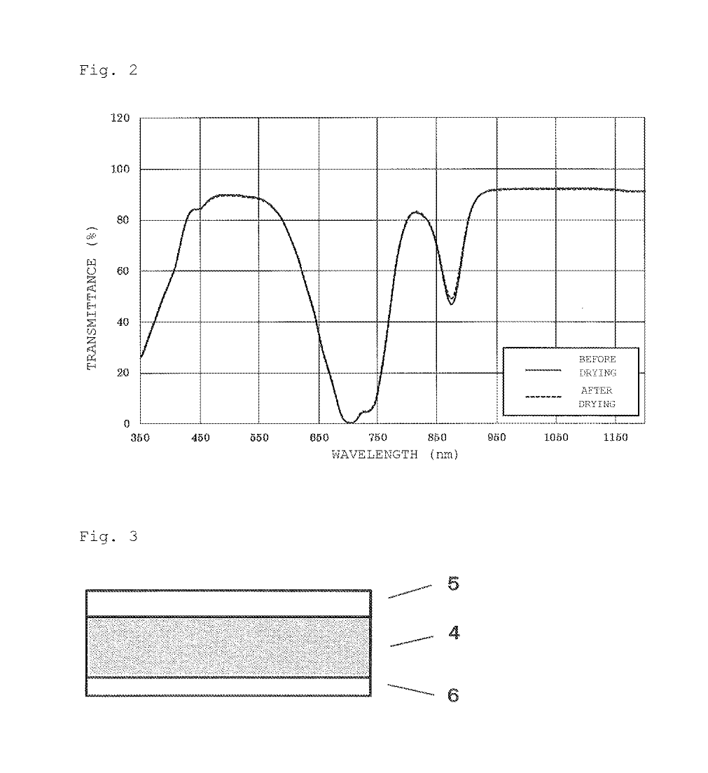

A base material (1) formed of a transparent resin substrate containing the compound (S) and the compound (P) was obtained in the same manner under the same conditions as those in Example 1. A spectral transmittance of this base material (1) was measured, and (Ta) was determined. After the measurement, the base material (1) was dried at 150° C. for 1 hour and furthermore at 200° C. for 15 minutes, thereafter a spectral transmittance of the base material (1) was again measured, and (Tb) and (Sr) were determined. The glass transition temperature of the base material (1) was also measured. The results are set forth in FIG. 2 and Table 11.

Subsequently, one surface of the transparent resin substrate was coated with a resin composition (1) having the following formulation by a bar coater, and the composition was heated at 70° C. for 2 minutes in an oven to remove the solvent by volatilization. In this coating, the coating conditions using the bar coater were controlled so that the thickness after drying might become 2 μm. Next, using a conveyer type exposure device, exposure (exposure quantity: 500 mJ/cm², 200 mW) was carried out to cure the resin composition (1), whereby a resin layer was formed on the transparent resin substrate. Such a resin layer formed from the resin composition (1) was also formed on the other surface of the transparent resin substrate in the same manner, whereby a base material (2) formed from the resin layer was obtained on each of both surfaces of the transparent resin substrate containing the compound (S) and the antioxidant (P).

Resin composition (1):

tricyclodecane dimethanol acrylate 60 parts by weight,
dipentaerythritol hexaacrylate 40 parts by weight,
1-hydroxycyclohexyl phenyl ketone 5 parts by weight,
methyl ethyl ketone (solvent, solid concentration (TSC): 30%)

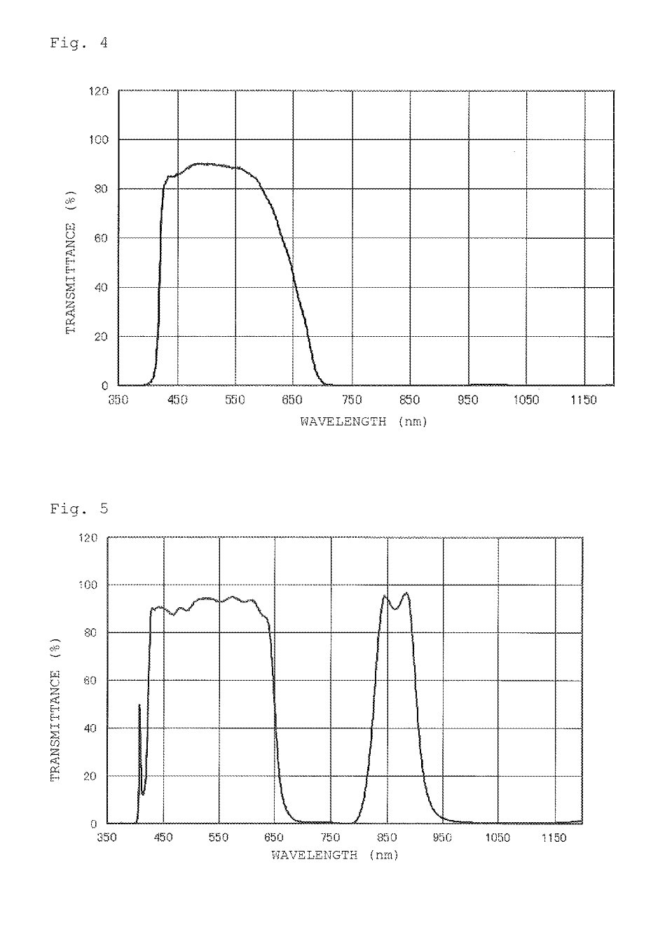

Subsequently, in the same manner as in Example 1, a dielectric multilayer film (I) was formed as a first optical layer on one surface of the resulting base material (2), and further, a dielectric multilayer film (II) was formed as a second optical layer on the other surface of the base material (2), whereby an optical filter having a thickness of about 0.104 mm was obtained. A spectral transmittance measured in the perpendicular direction to the resulting optical filter was measured, and optical properties in each wavelength region were evaluated. The results are set forth in FIG. 4 and Table 11.

### Example 3

A base material (1) formed of a transparent resin substrate containing the compound (S) and the antioxidant (P), a base material (2) having resin layers on both surfaces of the transparent resin substrate, and an optical filter were obtained in the same manner under the same conditions as those in Example 2, except that 0.3 parts of the compound (p-2) (melting point: 146 to 152° C.) was used instead of 0.3 parts of the compound (p-1) in Example 2. The evaluation results of the resulting base material and optical filter are set forth in Table 11.

### Example 4

A base material (1) formed of a transparent resin substrate containing the compound (S) and the antioxidant (P), a base material (2) having resin layers on both surfaces of the transparent resin substrate, and an optical filter were obtained in the same manner under the same conditions as those in Example 2, except that 0.3 parts of the compound (p-3) (melting point: 234 to 240° C.) was used instead of 0.3 parts of the compound (p-1) in Example 2. The evaluation results of the resulting base material and optical filter are set forth in Table 11.

### Example 5

A base material (1) formed of a transparent resin substrate containing the compound (S) and the antioxidant (P), a base material (2) having resin layers on both surfaces of the transparent resin substrate, and an optical filter were obtained in the same manner under the same conditions as those in Example 2, except that 0.3 parts of the compound (p-4) (melting point: 115° C.) was used instead of 0.3 parts of the compound (p-1) in Example 2. The evaluation results of the resulting base material and optical filter are set forth in Table 11.

### Example 6

A base material (1) formed of a transparent resin substrate containing the compound (S), the antioxidant (P) and the antioxidant (Q), a base material (2) having resin layers on both surfaces of the transparent resin substrate, and an optical filter were obtained in the same manner under the same conditions as those in Example 2, except that 0.3 parts of the compound (q-1) (melting point: 110 to 130° C.), in addition to 0.3 parts of the compound (p-1), was used as the antioxidant (Q) in Example 2. The evaluation results of the resulting base material and optical filter are set forth in Table 11.

### Examples 7 to 17

Base materials and optical filters were prepared in the same manner as in Example 2, except that the resin, the solvent, the drying conditions for the resin substrate, the compound (S), and the antioxidant (P) were changed as shown in Table 11. The evaluation results of the resulting base materials and optical filters are set forth in Table 11.

### Example 18

In Example 18, an optical filter which had a base material (3) formed of a resin substrate having a transparent resin layer containing the compound (S) and the antioxidant (P) on both surfaces was prepared according to the following procedure and conditions.

A resin substrate was prepared in the same manner as in Example 1, except that the resin A obtained in Resin Synthesis Example 1 and methylene chloride were placed in a container to prepare a solution having a resin concentration of 23% by weight and the resulting solution was used.

On both surfaces of the resulting resin substrate, resin layers formed from a resin composition (2) of the following formulation were formed in the same manner as in Example 2, whereby a base material (3) formed of the resin substrate having transparent resin layers containing the compound (S) and the antioxidant (P) on both surfaces was obtained. A spectral transmittance of this base material (3) was measured, and (Ta) was determined. After the measurement, the base material (3) was dried at 150° C. for 1 hour and furthermore at 200° C. for 15 minutes, thereafter a spectral transmittance of the base material (3) was again measured, and (Tb) and (Sr) were determined. The results are set forth in Table 11.

Resin composition (2):

tricyclodecane dimethanol acrylate 100 parts by weight,
1-hydroxycyclohexyl phenyl ketone 4 parts by weight,
compound (s-1) 0.125 parts by weight,
compound (s-2) 1.0 part by weight,
compound (s-3) 2.25 parts by weight,
antioxidant (p-1) 7.5 parts by weight,
methyl ethyl ketone (solvent, TSC: 25%).

Subsequently, in the same manner as in Example 1, a dielectric multilayer film (I) constituted of silica (SiO₂) layers and titania (TiO₂) layers alternatively laminated (total: 26 layers) was formed as a first optical layer on one surface of the resulting base material (3), and further, a dielectric multilayer film (II) constituted of silica (SiO₂) layers and titania (TiO₂) layers alternatively laminated (total: 20 layers) was formed as a second optical layer on the other surface of the base material (3), whereby an optical filter having a thickness of about 0.108 mm was obtained. A spectral transmittance measured in the perpendicular direction to the resulting optical filter was measured, and optical properties in each wavelength region were evaluated. The results are set forth in Table 11.

### Example 19

In Example 19, an optical filter which had a base material (4) formed of a transparent glass substrate having a transparent resin layer containing the compound (S) and the antioxidant (P) on one surface was prepared according to the following procedure and conditions.

A transparent glass substrate “OA-10G (thickness: 200 μm)” (available from Nippon Electric Glass Co., Ltd.) having been cut into a length of 60 mm and a width of 60 mm was coated with a resin composition (3) of the following formulation by a spin coater, and on a hot plate, the composition was heated at 80° C. for 2 minutes to remove the solvent by volatilization. In this coating, the coating conditions using the spin coater were controlled so that the thickness after drying might become 2 μm. Next, using a conveyer type exposure device, exposure (exposure quantity: 500 mJ/cm², 200 mW) was carried out to cure the resin composition (3), whereby a base material (4) formed of a transparent glass substrate having a transparent resin layer containing the compound (S) and the antioxidant (P) was obtained. A spectral transmittance of the base material (4) was measured, and (Ta) was determined. After the measurement, the base material (4) was dried at 150° C. for 1 hour and furthermore at 200° C. for 15 minutes, thereafter a spectral transmittance of the base material (4) was again measured, and (Tb) and (Sr) were determined. The results are set forth in Table 11.

Resin composition (3):

tricyclodecane dimethanol acrylate 20 parts by weight,
dipentaerythritol hexaacrylate 80 parts by weight,
1-hydroxycyclohexyl phenyl ketone 4 parts by weight,
compound (s-27) 0.25 parts by weight,
compound (s-60) 2.0 parts by weight,
compound (s-76) 4.5 parts by weight,
compound (p-1) 15 parts by weight,
methyl ethyl ketone (solvent, TSC: 35%).

Subsequently, in the same manner as in Example 1, a dielectric multilayer film (I) was formed as a first optical layer on one surface of the resulting base material (4), and further, a dielectric multilayer film (II) was formed as a second optical layer on the other surface of the base material, whereby an optical filter having a thickness of about 0.108 mm was obtained. A spectral transmittance measured in the perpendicular direction to the resulting optical filter was measured, and optical properties in each wavelength region were evaluated. The results are set forth in Table 11.

### Example 20

A base material (1) formed of a transparent resin substrate containing the compound (S) and the antioxidant (P), and a base material (2) having resin layers on both surfaces of the transparent resin substrate were obtained in the same manner under the same conditions as those in Example 2, except that 0.03 parts of compound (S) represented by the following formula (s-5) was used instead of 0.005 parts of compound (s-27) in Example 2. The optical properties of the resulting base material and the glass transition temperature of the base material are shown below.

(Ta): 1.3%,

(Tb): 1.5%,

Dye residual rate (Sr): 2.5%,

Glass transition temperature of base material: 162° C.

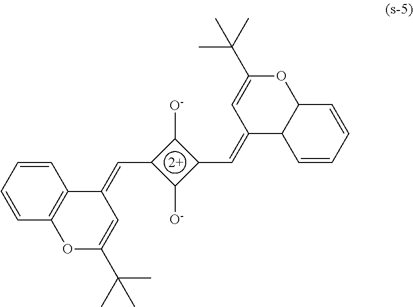

Subsequently, a dielectric multilayer film (III) was formed on one surface of the resulting base material, and further, a dielectric multilayer film (IV) was formed on the other surface of the base material, whereby an optical filter having a thickness of about 0.104 mm was obtained.

The dielectric multilayer film (III) was constituted of silica (SiO₂) layers and titania (TiO₂) layers that had been alternately laminated at a deposition temperature of 100° C. (total: 24 layers). The dielectric multilayer film (IV) was constituted of silica (SiO₂) layers and titania (TiO₂) layers that had been alternately laminated at a deposition temperature of 100° C. (total: 18 layers). In each of the dielectric multilayer films (III) and (IV), the silica layers and the titania layers were alternately laminated in the order of a titania layer, a silica layer, a titania layer, - - - a silica layer, a titania layer and a silica layer from the base material side, and the outermost layer of the optical filter was a silica layer.

Designing of the dielectric multilayer films (III) and (IV) was carried out in the following manner.

The thickness of each layer and the number of layers were optimized according to the dependence of the base material refractive index on the wavelength and the absorption properties of the applied compound (S) so that the reflection prevention effect in the visible region and the selective transmission/reflection performance in the near-infrared region could be attained, by the use of optical thin film design software (Essential Macleod, available from Thin Film Center, Inc.). When optimization was carried out, input parameters (Target values) into the software in this Example were set as shown in the following Table 9.

TABLE 9

| | | Input parameter into software | | | |
|---|---|---|---|---|---|
| Dielectric | | | Re- | | |
| multilayer | Wavelength | Incident | quired | Target | |
| film | (nm) | Angle | Value | Tolerance | Type |
| (III) | 410 to 650 | 0 | 100 | 1 | Transmittance |
| | 655 to 815 | 0 | 0 | 0.5 | Transmittance |
| | 520 to 890 | 0 | 100 | 0.5 | Transmittance |
| (IV) | 420 to 700 | 0 | 100 | 1 | Transmittance |
| | 825 to 890 | 0 | 100 | 0.5 | Transmittance |
| | 910 to 1200 | 0 | 0 | 0.5 | Transmittance |

As a result of optimization of film constitution, the dielectric multilayer film (III) became a multilayer deposited film of 24 lamination layers, the film being constituted of silica layers each having a film thickness of 13 to 174 nm and titania layers each having a film thickness of 9 to 200 nm alternately laminated and the dielectric multilayer film (IV) became a multilayer deposited film of 18 lamination layers, the film being constituted of silica layers each having a film thickness of 41 to 198 nm and titania layers each having a film thickness of 12 to 122 nm alternately laminated, in Example 1. An example of the film constitution obtained by optimization is shown in Table 10.

TABLE 10

| Dielectric | | Film | Physical film | Optical film |
|---|---|---|---|---|
| multilayer film | Layer | material | thickness (nm) | thickness (nd) |
| (III) | 1 | SiO₂ | 79.9 | 0.21λ |
| | 2 | TiO₂ | 79.9 | 0.351λ |
| | 3 | SiO₂ | 160.2 | 0.421λ |
| | 4 | TiO₂ | 194.6 | 0.855λ |
| | 5 | SiO₂ | 155.8 | 0.41λ |
| | 6 | TiO₂ | 74.6 | 0.328λ |
| | 7 | SiO₂ | 147.6 | 0.388λ |
| | 8 | TiO₂ | 81.1 | 0.356λ |
| | 9 | SiO₂ | 53.6 | 0.141λ |
| | 10 | TiO₂ | 12.3 | 0.054λ |
| | 11 | SiO₂ | 64.8 | 0.17λ |
| | 12 | TiO₂ | 24.1 | 0.106λ |
| | 13 | SiO₂ | 173.8 | 0.457λ |
| | 14 | TiO₂ | 76.5 | 0.336λ |
| | 15 | SiO₂ | 156.2 | 0.411λ |
| | 16 | TiO₂ | 199.9 | 0.878λ |
| | 17 | SiO₂ | 167.5 | 0.441λ |
| | 18 | TiO₂ | 84.8 | 0.030λ |
| | 19 | SiO₂ | 12.5 | 0.080λ |
| | 20 | TiO₂ | 20.8 | 0.091λ |
| | 21 | SiO₂ | 33.9 | 0.089λ |
| | 22 | TiO₂ | 13.3 | 0.059λ |
| | 23 | SiO₂ | 44.2 | 0.116λ |
| | 24 | TiO₂ | 8.9 | 0.039λ |

Base material

| | | | | |
|---|---|---|---|---|
| (IV) | 25 | TiO₂ | 12.1 | 0.053λ |
| | 26 | SiO₂ | 40.6 | 0.107λ |
| | 27 | TiO₂ | 121.5 | 0.534λ |
| | 28 | SiO₂ | 186.3 | 0.49λ |
| | 29 | TiO₂ | 115.2 | 0.506λ |
| | 30 | SiO₂ | 197.6 | 0.52λ |
| | 31 | TiO₂ | 115.1 | 0.505λ |
| | 32 | SiO₂ | 186.4 | 0.49λ |
| | 33 | TiO₂ | 110.5 | 0.485λ |
| | 34 | SiO₂ | 179.4 | 0.472λ |
| | 35 | TiO₂ | 107.3 | 0.471λ |
| | 36 | SiO₂ | 185.2 | 0.470λ |
| | 37 | TiO₂ | 117.1 | 0.514λ |
| | 38 | SiO₂ | 191.0 | 0.502λ |
| | 39 | TiO₂ | 113.3 | 0.498λ |
| | 40 | SiO₂ | 193.4 | 0.470λ |
| | 41 | TiO₂ | 111.2 | 0.488λ |
| | 42 | SiO₂ | 89.6 | 0.236λ |

*λ = 550 nm

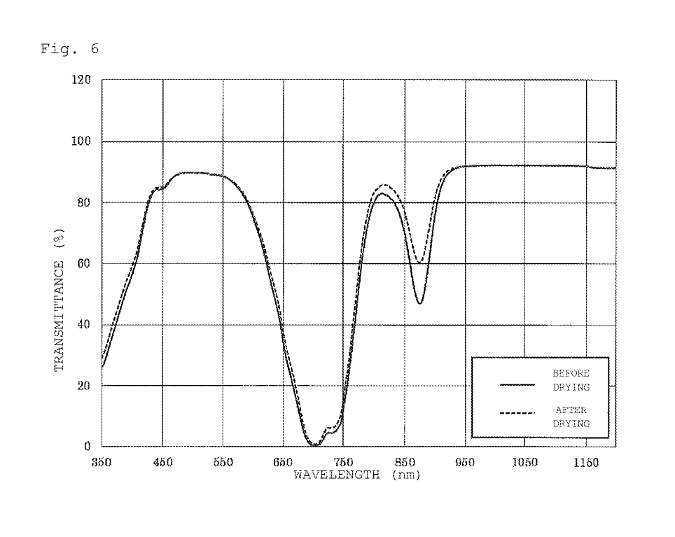

A spectral transmittance measured in the perpendicular direction to the resulting optical filter was measured, and optical properties in each wavelength region were evaluated. The results are set forth in FIG. 5.

### Comparative Example 1

A base material and an optical filter were prepared in the same manner as in Example 2, except that the antioxidant (P) was not used in Example 2. The evaluation results of the resulting base material and optical filter are set forth in FIG. 6 and Table 11.

### Comparative Example 2

A base material formed of a transparent resin substrate containing the compound (S) and the antioxidant (Q) and an optical filter were obtained in the same manner under the same conditions as those in Example 2, except that 0.3 parts of the compound (q-2) (melting point: 119° C.) was used as the antioxidant (Q) instead of 0.3 parts of the compound (p-1) as the antioxidant (P) in Example 2. The evaluation results of the resulting base material (1), the resulting base material (2) having resin layers on both surfaces of the transparent resin substrate, and the resulting optical filter are set forth in Table 11.

### Comparative Example 3

A base material (1) formed of a transparent resin substrate containing the compound (S) and the antioxidant (Q), a base material (2) having resin layers on both surfaces of the transparent resin substrate, and an optical filter were obtained in the same manner under the same conditions as those in Example 2, except that 0.3 parts of the compound (q-3) (melting point: 49 to 52° C.) was used as the antioxidant (Q) instead of 0.3 parts of the compound (p-1) as the antioxidant (P) in Example 2. The evaluation results of the resulting base material and optical filter are set forth in Table 11.

Details of constitution of the base materials, various compounds, etc. applied to the examples and the comparative examples are as follows.

<Form of Base Material>

Base material (1): a form made of a transparent resin substrate containing a compound (S) and an antioxidant (P)

Base material (2): a form having resin layers on both surfaces of a transparent resin substrate containing a compound (S) and an antioxidant (P)

Base material (3): a form having transparent resin layers containing a compound (S) and an antioxidant (P), on both surfaces of a resin substrate

Base material (4): a form made of glass substrate

<Transparent Resin>

Resin A: cyclic olefin-based resin (Resin Synthesis Example 1)

Resin B: aromatic polyether-based resin (Resin Synthesis Example 2)

Resin C: polyimide-based resin (Resin Synthesis Example 3)

Resin D: cyclic olefin-based resin “Zeonor 1420R” (available from Zeon Corporation)

<Glass Substrate>

Glass substrate (1): a transparent glass substrate “OA-10G (thickness: 200 μm)” (available from Nippon Electric Glass Co., Ltd.) having been cut into a length of 60 mm and a width of 60 mm

<Near-Infrared Absorbing Dye>

<<Compound (S)>>

Compound (s-27): compound (s-27) described above (absorption maximum wavelength in dichloromethane: 868 nm)

Compound (s-60): compound (s-60) described above (absorption maximum wavelength in dichloromethane: 703 nm)

Compound (s-76): compound (s-76) described above (absorption maximum wavelength in dichloromethane: 736 nm)

Compound (s-104): compound (s-104) described above (absorption maximum wavelength in dichloromethane: 1093 nm)

Compound (s-5): compound (s-5) described above (absorption maximum wavelength in dichloromethane: 770 nm)

<Antioxidant>

<<Antioxidant (P)>>

Compound (p-1): compound (p-1) described above (melting point: 180 to 190° C.)

Compound (p-2): compound (p-2) described above (melting point: 146 to 152° C.)

Compound (p-3): compound (p-3) described above (melting point: 234 to 240° C.)

Compound (p-4): compound (p-4) described above (melting point: 115° C.)

<<Antioxidant (Q)>>

Compound (q-1): compound (q-1) described above (melting point: 110 to 130° C.)

Compound (q-2): compound (q-2) described above (melting point: 119° C.)

Compound (q-3): compound (q-3) described above (melting point: 49 to 52° C.)

<Solvent>

Solvent (1): methylene chloride

Solvent (2): N,N-dimethylacetamide

Solvent (3): cyclohexane/xylene (ratio by weight: 7/3)

The drying conditions for the (transparent) resin substrates of the examples and the comparative examples in Table 11 are as follows. The coating film was peeled from the glass plate before drying under reduced pressure.

<Film Drying Conditions>

Condition (1): 20° C./8 hr→100° C./8 hr under reduced pressure→150° C./1 hr→200° C./15 min

Condition (2): 20° C./8 hr→100° C./8 hr under reduced pressure→150° C./1 hr→190° C./15 min

Condition (3): 20° C./8 hr→100° C./8 hr under reduced pressure→150° C./1 hr→180° C./15 min

TABLE 11

| | | | | Examples | | | | | |
|---|---|---|---|---|---|---|---|---|---|
| | | | | 1 | 2 | 3 | 4 | 5 | 6 |
| Base | Form of base material | | | (1) | (2) | (2) | (2) | (2) | (2) |
| material | Formulation of | Transparent | Resin A | 100 | 100 | 100 | 100 | 100 | 100 |
| constitution | transparent | resin (weight | Resin B | | | | | | |
| | resin substrate | part(s)) | Resin C | | | | | | |
| | or resin support | | Resin D | | | | | | |
| | | Compound | s-27 | 0.005 | 0.005 | 0.005 | 0.005 | 0.005 | 0.005 |
| | | (S) (weight | s-60 | 0.04 | 0.04 | 0.04 | 0.04 | 0.04 | 0.04 |
| | | part(s)) | s-76 | 0.09 | 0.09 | 0.09 | 0.09 | 0.09 | 0.09 |
| | | | s-104 | | | | | | |
| | | Antioxidant | p-1 | 0.3 | 0.3 | | | | 0.3 |
| | | (P) (weight | p-2 | | | 0.3 | | | |
| | | part(s)) | p-3 | | | | 0.3 | | |
| | | | p-4 | | | | | 0.3 | |
| | | Antioxidant | q-1 | | | | | | 0.3 |
| | | (Q) (weight | q-2 | | | | | | |
| | | part(s)) | q-3 | | | | | | |

| | | | | | | |
|---|---|---|---|---|---|---|
| Solvent | (1) | (1) | (1) | (1) | (1) | (1) |

| | | | | | | |
|---|---|---|---|---|---|---|
| Drying conditions | (1) | (1) | (1) | (1) | (1) | (1) |
| Glass substrate | — | — | — | — | — | — |
| (Transparent) resin layer-forming | — | (1) | (1) | (1) | (1) | (1) |
| composition | | | | | | |

| Glass transition temperature of base material (° C.) | | 162 | 162 | 161 | 163 | 160 | 161 |
|---|---|---|---|---|---|---|---|
| Base material optical properties | Ta (%) | 47 | 47 | 47 | 47 | 47 | 47 |
| | Tb (%) | 49 | 49 | 49 | 50 | 50 | 49 |
| | Sr (%) | 96 | 96 | 96 | 93 | 92 | 96 |
| Dielectric multilayer film | Number of layers | 26 | 26 | 26 | 26 | 26 | 26 |
| (both-side constitution) | on one side | | | | | | |
| | Number of layers | 20 | 20 | 20 | 20 | 20 | 20 |
| | on one side | | | | | | |
| Optical properties of optical | Average | 89 | 89 | 89 | 90 | 90 | 89 |
| filter | transmittances | | | | | | |
| | in wavelength | | | | | | |
| | region of 430 | | | | | | |
| | to 580 nm (%) | | | | | | |
| | Average | 1%≥ | 1%≥ | 1%≥ | 1%≥ | 1%≥ | 1%≥ |
| | transmittances | | | | | | |
| | in wavelength | | | | | | |
| | region of 800 | | | | | | |
| | to 1000 nm (%) | | | | | | |

| | | | | Examples | | | | |
|---|---|---|---|---|---|---|---|---|
| | | | | 7 | 8 | 9 | 10 | 11 |
| Base | Form of base material | | | (2) | (2) | (2) | (2) | (2) |
| material | Formulation of | Transparent | Resin A | 100 | 100 | 100 | 100 | 100 |
| constitution | transparent | resin (weight | Resin B | | | | | |
| | resin substrate | part(s)) | Resin C | | | | | |
| | or resin support | | Resin D | | | | | |
| | | Compound | s-27 | 0.005 | 0.005 | 0.005 | | |
| | | (S) (weight | s-60 | 0.04 | 0.04 | | 0.04 | |
| | | part(s)) | s-76 | 0.09 | 0.09 | | | 0.09 |
| | | | s-104 | | | | | |
| | | Antioxidant | p-1 | 0.3 | 0.3 | 0.3 | 0.3 | 0.3 |
| | | (P) (weight | p-2 | | | | | |
| | | part(s)) | p-3 | | | | | |
| | | | p-4 | | | | | |
| | | Antioxidant | q-1 | | | | | |
| | | (Q) (weight | q-2 | | | | | |
| | | part(s)) | q-3 | | | | | |

| | | | | | |
|---|---|---|---|---|---|
| Solvent | (1) | (1) | (1) | (1) | (1) |

| | | | | | |
|---|---|---|---|---|---|
| Drying conditions | (2) | (3) | (1) | (1) | (1) |
| Glass substrate | — | — | — | — | — |
| (Transparent) resin layer-forming | (1) | (1) | (1) | (1) | (1) |
| composition | | | | | |

| Glass transition temperature of base material (° C.) | | 162 | 162 | 162 | 162 | 162 |
|---|---|---|---|---|---|---|
| Base material optical properties | Ta (%) | 47 | 47 | 47 | 47 | 47 |
| | Tb (%) | 49 | 49 | 50 | 48 | 48 |
| | Sr (%) | 96 | 97 | 94 | 98 | 98 |
| Dielectric multilayer film | Number of layers | 26 | 26 | 26 | 26 | 26 |
| (both-side constitution) | on one side | | | | | |
| | Number of layers | 20 | 20 | 20 | 20 | 20 |
| | on one side | | | | | |
| Optical properties of optical | Average | 89 | 89 | 91 | 91 | 91 |
| filter | transmittances | | | | | |
| | in wavelength | | | | | |
| | region of 430 | | | | | |
| | to 580 nm (%) | | | | | |
| | Average | 1%≥ | 1%≥ | 1%≥ | 1%≥ | 1%≥ |
| | transmittances | | | | | |
| | in wavelength | | | | | |
| | region of 800 | | | | | |
| | to 1000 nm (%) | | | | | |

| | | | | Examples | | | | | | |
|---|---|---|---|---|---|---|---|---|---|---|
| | | | | 12 | 13 | 14 | 15 | 16 | 17 | 18 |
| Base | Form of base material | | | (2) | (2) | (2) | (2) | (2) | (2) | (3) |
| material | Formulation of | Transparent | Resin A | | | | 100 | 100 | 100 | 100 |
| constitution | transparent | resin (weight | Resin B | 100 | | | | | | |
| | resin substrate | part(s)) | Resin C | | 100 | | | | | |
| | or resin support | | Resin D | | | 100 | | | | |
| | | Compound | s-27 | 0.005 | 0.005 | 0.005 | 0.005 | 0.005 | | |
| | | (S) (weight | s-60 | 0.04 | 0.04 | 0.04 | 0.04 | 0.04 | 0.04 | |
| | | part(s)) | s-76 | 0.09 | 0.09 | 0.09 | 0.09 | 0.09 | 0.09 | |
| | | | s-104 | | | | | | 0.08 | |
| | | Antioxidant | p-1 | 0.3 | 0.3 | 0.3 | 0.6 | 0.9 | 0.3 | |
| | | (P) (weight | p-2 | | | | | | | |
| | | part(s)) | p-3 | | | | | | | |
| | | | p-4 | | | | | | | |
| | | Antioxidant | q-1 | | | | | | | |
| | | (Q) (weight | q-2 | | | | | | | |
| | | part(s)) | q-3 | | | | | | | |

| | | | | | | | |
|---|---|---|---|---|---|---|---|
| Solvent | (2) | (2) | (3) | (1) | (1) | (1) | (1) |

| | | | | | | | |
|---|---|---|---|---|---|---|---|
| Drying conditions | (1) | (1) | (1) | (1) | (1) | (1) | (1) |
| Glass substrate | — | — | — | — | — | — | — |
| (Transparent) resin layer-forming | (1) | (1) | (1) | (1) | (1) | (1) | (2) |
| composition | | | | | | | |

| Glass transition temperature of base material (° C.) | | 283 | 308 | 134 | 160 | 158 | 160 | — |
|---|---|---|---|---|---|---|---|---|
| Base material optical properties | Ta (%) | 47 | 47 | 47 | 47 | 47 | 26 | 47 |
| | Tb (%) | 49 | 49 | 49 | 49 | 49 | 29 | 49 |
| | Sr (%) | 96 | 96 | 96 | 97 | 97 | 9.3 | 96 |
| Dielectric multilayer film | Number of layers | 26 | 26 | 26 | 26 | 26 | 26 | 26 |
| (both-side constitution) | on one side | | | | | | | |
| | Number of layers | 20 | 20 | 20 | 20 | 20 | 20 | 20 |
| | on one side | | | | | | | |
| Optical properties of optical | Average | 88 | 88 | 89 | 88 | 88 | 87 | 89 |
| filter | transmittances | | | | | | | |
| | in wavelength | | | | | | | |
| | region of 430 | | | | | | | |
| | to 580 nm (%) | | | | | | | |
| | Average | 1%≥ | 1%≥ | 1%≥ | 1%≥ | 1%≥ | 1%≥ | 1%≥ |
| | transmittances | | | | | | | |
| | in wavelength | | | | | | | |
| | region of 800 | | | | | | | |
| | to 1000 nm (%) | | | | | | | |

| | | | | Examples | Comparative Examples | | |
|---|---|---|---|---|---|---|---|
| | | | | 19 | 1 | 2 | 3 |
| Base | Form of base material | | | (4) | (1) | (1) | (1) |
| material | Formulation of | Transparent | Resin A | | 100 | 100 | 100 |
| constitution | transparent | resin (weight | Resin B | | | | |
| | resin substrate | part(s)) | Resin C | | | | |
| | or resin support | | Resin D | | | | |
| | | Compound | s-27 | | 0.005 | 0.005 | 0.005 |
| | | (S) (weight | s-60 | | 0.04 | 0.04 | 0.04 |
| | | part(s)) | s-76 | | 0.09 | 0.09 | 0.09 |
| | | | s-104 | | | | |
| | | Antioxidant | p-1 | | | | |
| | | (P) (weight | p-2 | | | | |
| | | part(s)) | p-3 | | | | |
| | | | p-4 | | | | |
| | | Antioxidant | q-1 | | | | |
| | | (Q) (weight | q-2 | | | 0.3 | |
| | | part(s)) | q-3 | | | | 0.3 |

| | | | | |
|---|---|---|---|---|
| Solvent | — | (1) | (1) | (1) |

| | | | | |
|---|---|---|---|---|
| Drying conditions | — | (1) | (1) | (1) |
| Glass substrate | (1) | — | — | — |
| (Transparent) resin layer-forming | (3) | (1) | (1) | (1) |
| composition | | | | |

| Glass transition temperature of base material (° C.) | | — | 164 | 160 | 150 |
|---|---|---|---|---|---|
| Base material optical properties | Ta (%) | 47 | 47 | 47 | 47 |
| | Tb (%) | 49 | 60 | 52 | 54 |
| | Sr (%) | 96 | 66 | 87 | 82 |
| Dielectric multilayer film | Number of layers | 26 | 26 | 26 | 26 |
| (both-side constitution) | on one side | | | | |
| | Number of layers | 20 | 20 | 20 | 20 |
| | on one side | | | | |
| Optical properties of optical | Average | 90 | 90 | 90 | 90 |
| filter | transmittances | | | | |
| | in wavelength | | | | |
| | region of 430 | | | | |
| | to 580 nm (%) | | | | |
| | Average | 1%≥ | 1%≥ | 1%≥ | 1%≥ |
| | transmittances | | | | |
| | in wavelength | | | | |
| | region of 800 | | | | |
| | to 1000 nm (%) | | | | |

### INDUSTRIAL APPLICABILITY

The optical filter of the present invention can be favorably used for digital still camera, camera for a cellular phone, digital video camera, camera for a personal computer, surveillance camera, camera for automobile, TV, vehicle equipment for car navigation system, personal digital assistant, video game console, handheld game console, equipment for fingerprint authentication system, digital music player, etc. Moreover, the optical filter is useful also as a heat ray cut filter mounted on glass of an automobile, building or the like.

### REFERENCE SIGNS LIST

1: optical filter
2: spectrophotometer
3: light
4: base material (i)
5: dielectric multilayer film (I)
6: dielectric multilayer film (II)

1: An optical filter, comprising:
a base material comprising a compound having an absorption maximum in a region of from 600 to 1150 nm and an antioxidant having at least one phosphorus atom in a molecule; and
a dielectric multilayer film formed on at least one surface of the base material.

2: The optical filter according to claim 1, wherein the base material further comprises a resin.

3: The optical filter according to claim 2, wherein the resin is a transparent resin.

4: The optical filter according to claim 3, wherein a content of the antioxidant is in a range of from 0.1 to 3.0 parts by weight based on 100 parts by weight of the transparent resin.

5: The optical filter according to claim 1 wherein a melting point of the antioxidant is from 100 to 250° C.

6: The optical filter according to claim 1, wherein the antioxidant is a compound having a structure represented by formula (p): 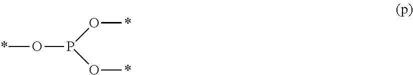 [SMILES: *OP(O*)O*]
wherein * represents a bond.

7: The optical filter according to claim 1, wherein the antioxidant is at least one selected from compounds represented by formulae (I) to (III): 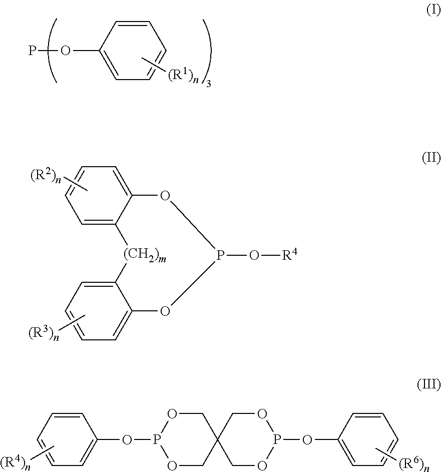
wherein R¹ to R⁵ are each independently a hydrogen atom; a halogen atom; a substituted or unsubstituted hydrocarbon group of 1 to 30 carbon atoms, which optionally has a linking group containing an oxygen atom, a sulfur atom, a nitrogen atom or a silicon atom; or a polar group, n is an integer of 0 to 5, and m is 0 or 1.

8: The optical filter according to claim 3, wherein the transparent resin is at least one resin selected from the group consisting of a cyclic (poly)olefin-based resin, an aromatic polyether-based resin, a polyimide-based resin, a fluorene polycarbonate-based resin, a fluorene polyester-based resin, a polycarbonate-based resin, a polyamide-based resin, a polyarylate-based resin, a polysulfone-based resin, a polyether sulfone-based resin, a polyparaphenylene-based resin, a polyamideimide-based resin, a polyethylene naphthalate-based resin, a fluorinated aromatic polymer-based resin, a (modified) acrylic-based resin, an epoxy-based resin, an allyl ester-based curing type resin, a silsesquioxane-based ultraviolet curing resin, an acrylic-based ultraviolet curing resin and a vinyl-based ultraviolet curing resin.

9: The optical filter according to claim 1, which selectively transmits visible rays and a part of near-infrared rays.

10: A solid-state image pickup device equipped with the optical filter according to claim 1.

11: A camera module equipped with the optical filter according to claim 1.
